(19) United States
(12) Patent Application Publication
(10) Pub. No.: US 2024/0215348 A1
(43) Pub. Date: Jun. 27, 2024

(54) ARRAY SUBSTRATE AND DISPLAY APPARATUS

(71) Applicants: Chengdu BOE Optoelectronics Technology Co., Ltd., Chengdu, Sichuan (CN); BOE Technology Group Co., Ltd., Beijing (CN)

(72) Inventors: Binyan Wang, Beijing (CN); Pinchao Gu; Long Ma; Tianyi Cheng

(73) Assignees: Chengdu BOE Optoelectronics Technology Co., Ltd., Chengdu, Sichuan (CN); BOE Technology Group Co., Ltd., Beijing (CN)

(21) Appl. No.: 17/996,382

(22) PCT Filed: Dec. 22, 2021
(86) PCT No.: PCT/CN2021/140582

§ 371 Date: Oct. 17, 2022

(51) Int. Cl. H10K 59/131; H10K 59/121

(52) U.S. Cl. CPC H10K 59/131; H10K 59/1213; H10K 59/1216

(57) ABSTRACT

An array substrate is provided. The array substrate includes a first adjacent data line and a second adjacent data line extending along a first direction. The first adjacent data line and the second adjacent data line extend from a same inter-column region between a first column of pixel driving circuit and a second column of pixel driving circuit in a display area into a boundary area between the first column of pixel driving circuit and a peripheral area. In the boundary area, the first adjacent data line and the second adjacent data line are in a same layer.

### TECHNICAL FIELD

The present invention relates to display technology, more particularly, to an array substrate and a display apparatus.

### BACKGROUND

Organic Light Emitting Diode (OLED) display is one of the hotspots in the field of flat panel display research today. Unlike Thin Film Transistor-Liquid Crystal Display (TFT-LCD), which uses a stable voltage to control brightness, OLED is driven by a driving current required to be kept constant to control illumination. The OLED display panel includes a plurality of pixel units configured with pixel-driving circuits arranged in multiple rows and columns. Each pixel-driving circuit includes a driving transistor having a gate terminal connected to one gate line per row and a drain terminal connected to one data line per column. When the row in which the pixel unit is gated is turned on, the switching transistor connected to the driving transistor is turned on, and the data voltage is applied from the data line to the driving transistor via the switching transistor, so that the driving transistor outputs a current corresponding to the data voltage to an OLED device. The OLED device is driven to emit light of a corresponding brightness.

### SUMMARY

In one aspect, the present disclosure provides an array substrate, comprising a first adjacent data line and a second adjacent data line extending along a first direction; wherein the first adjacent data line and the second adjacent data line extend from a same inter-column region between a first column of pixel driving circuit and a second column of pixel driving circuit in a display area into a boundary area between the first column of pixel driving circuit and a peripheral area; wherein, in the boundary area, the first adjacent data line and the second adjacent data line are in a same layer.

Optionally, the first column of pixel driving circuit is on a side of the first adjacent data line away from the second adjacent data line in the boundary area; and the second column of pixel driving circuit is absent on a side of the second adjacent data line away from the first adjacent data line in the boundary area.

Optionally, the array substrate further comprises a plurality of signal lines extending along a second direction from the boundary area into the peripheral area; wherein the first adjacent data line and the second adjacent data line are in a same layer where they cross over the plurality of signal lines.

Optionally, the array substrate further comprises a plurality of first layer switching structure in the boundary area; and a plurality of signal supply lines in the peripheral area respectively electrically connected to the plurality of signal lines in the boundary area; wherein a respective first layer switching structure connects a pair of signal line and signal supply line in different layers.

Optionally, the array substrate further comprises a column of layer switching structures in the boundary area; wherein, in the boundary area, the first adjacent data line and the second adjacent data line are between the first column of pixel driving circuit and the column of layer switching structures.

Optionally, the array substrate further comprises a first data signal supply line and a second data signal supply line outside the boundary area and in the peripheral area; wherein the first data signal supply line and the second data signal supply line are respectively connected to the first adjacent data line and the second adjacent data line respectively through a plurality of second layer switching structures; the first data signal supply line and the second data signal supply line are in different layers from each other, and are in layers different from the first adjacent data line and the second adjacent data line.

Optionally, the first adjacent data line and the second adjacent data line are between a first voltage supply line and a second voltage supply line; the first adjacent data line and the second adjacent data line are configured to provide data signals to the first column of pixel driving circuits and the second column of pixel driving circuits, respectively; and the first voltage supply line and the second voltage supply line are configured to provide power supply voltages to the first column of pixel driving circuits and the second column of pixel driving circuits, respectively.

Optionally, a respective pixel driving circuit comprises a second capacitor electrode connected to a respective voltage supply line; and a first semiconductor material layer comprising a second node portion, a boundary of which being defined by an active layer of a driving transistor, an active layer of a first transistor, and an active layer of a third transistor; wherein an orthographic projection of the second node portion on a base substrate is at least partially non-overlapping with an orthographic projection of the second capacitor electrode on the base substrate.

Optionally, the orthographic projection of the second node portion on the base substrate is at least 50% non-overlapping with an orthographic projection of the second capacitor electrode on the base substrate.

Optionally, the second capacitor electrode comprises a first part and a second part; an orthographic projection of the first part on the base substrate is at least 90% non-overlapping with the orthographic projection of the second node portion on the base substrate; and an orthographic projection of the second part on the base substrate is at least partially overlapping with the orthographic projection of the second node portion on the base substrate.

Optionally, the respective pixel driving circuit further comprises a voltage connecting pad connected to a first electrode of the third transistor, a respective voltage supply line, and the second capacitor electrode.

Optionally, the orthographic projection of the second part on the base substrate is at least 75% overlapping with an orthographic projection of the voltage connecting pad on the base substrate; and the orthographic projection of the first part on the base substrate is non-overlapping with the orthographic projection of the voltage connecting pad on the base substrate.

Optionally, the second node portion extends along a first direction crossing over a respective gate line; and a first maximum width of the first part along the first direction is greater than a second maximum width of the second part along the first direction by at least 30%.

Optionally, the array substrate comprises a first semiconductor material layer and a second semiconductor material layer; wherein the second semiconductor material layer comprise at least an active layer of a second transistor and at least an active layer of a first reset transistor; the first semiconductor material layer comprise at least an active layer of a driving transistor comprising a first semiconductor material; and active layers of the second transistor and the first reset transistor comprise a second semiconductor material different from the first semiconductor material.

Optionally, an orthographic projection of a respective voltage supply line on a base substrate covers at least 50% of an orthographic projection of the active layer of the second transistor on the base substrate, covers at least 50% of an orthographic projection of the active layer of the first reset transistor on the base substrate.

Optionally, the array substrate further comprises a respective second gate line connected to a gate electrode of a second transistor; the respective second gate line comprises a first branch in a second conductive layer and a second branch in a third conductive layer; and an orthographic projection of the first branch on a base substrate at least partially overlaps with an orthographic projection of the second branch on the base substrate.

Optionally, the array substrate further comprises a respective reset control signal line connected to a gate electrode of a first reset transistor; the respective reset control signal line comprises a first branch in a second conductive layer and a second branch in a third conductive layer; and an orthographic projection of the first branch on a base substrate at least partially overlaps with an orthographic projection of the second branch on the base substrate.

Optionally, a respective pixel driving circuit comprises a node connecting line, a second transistor, a first reset transistor, and a storage capacitor; wherein the node connecting line connects a first electrode of the second transistor and a second electrode of the first reset transistor to a first capacitor electrode of the storage capacitor; and an orthographic projection of a respective voltage supply line on a base substrate covers at least 50% of an orthographic projection of the node connecting line on the base substrate.

Optionally, at least a portion of the respective voltage supply line and at least a portion of the node connecting line have conforming contours.

In another aspect, the present disclosure provides a display apparatus, comprising the array substrate described herein, and an integrated circuit connected to the array substrate.

### BRIEF DESCRIPTION OF THE FIGURES

The following drawings are merely examples for illustrative purposes according to various disclosed embodiments and are not intended to limit the scope of the present invention.

FIG. 1 is a plan view of an array substrate in some embodiments according to the present disclosure.

FIG. 2 is a circuit diagram illustrating the structure of a pixel driving circuit in some embodiments according to the present disclosure.

FIG. 3A is a diagram illustrating the structure of two adjacent pixel driving circuits in a same stage in an array substrate in some embodiments according to the present disclosure.

FIG. 3B is a diagram illustrating the structure of a light shield layer of two adjacent pixel driving circuits in an array substrate depicted in FIG. 3A.

FIG. 3C is a diagram illustrating the structure of a first semiconductor material layer of two adjacent pixel driving circuits in an array substrate depicted in FIG. 3A.

FIG. 3D is a diagram illustrating the structure of a first conductive layer of two adjacent pixel driving circuits in an array substrate depicted in FIG. 3A.

FIG. 3E is a diagram illustrating the structure of a second conductive layer of two adjacent pixel driving circuits in an array substrate depicted in FIG. 3A.

FIG. 3F is a diagram illustrating the structure of a second semiconductor material layer of two adjacent pixel driving circuits in an array substrate depicted in FIG. 3A.

FIG. 3G is a diagram illustrating the structure of a third conductive layer of two adjacent pixel driving circuits in an array substrate depicted in FIG. 3A.

FIG. 3H is a diagram illustrating vias extending through a passivation layer, a second inter-layer dielectric layer, a first inter-layer dielectric layer, an insulating layer and a gate insulating layer in an array substrate depicted in FIG. 3A.

FIG. 3I is a diagram illustrating vias extending through a passivation layer and a second inter-layer dielectric layer in an array substrate depicted in FIG. 3A.

FIG. 3J is a diagram illustrating the structure of a first signal line layer of two adjacent pixel driving circuits in an array substrate depicted in FIG. 3A.

FIG. 3K is a diagram illustrating vias extending through a first planarization layer in an array substrate depicted in FIG. 3A.

FIG. 3L is a diagram illustrating vias extending through a passivation layer, a second inter-layer dielectric layer, a first inter-layer dielectric layer, an insulating layer and a gate insulating layer in an array substrate depicted in FIG. 3A.

FIG. 3M is a diagram illustrating the structure of a second signal line layer of two adjacent pixel driving circuits in an array substrate depicted in FIG. 3A.

FIG. 3N is a diagram illustrating vias extending through a second planarization layer in an array substrate depicted in FIG. 3A.

FIG. 3O is a diagram illustrating the structure of an anode layer of two adjacent pixel driving circuits in an array substrate in some embodiments according to the present disclosure.

FIG. 3P is a diagram illustrating the structure of a pixel definition layer of two adjacent pixel driving circuits in an array substrate in some embodiments according to the present disclosure.

FIG. 4A is a cross-sectional view along an A-A′ line in FIG. 3A.

FIG. 4B is a cross-sectional view along a B-B′ line in FIG. 3A.

FIG. 4C is a cross-sectional view along a C-C′ line in FIG. 3A.

FIG. 4D is a cross-sectional view along a D-D′ line in FIG. 3A.

FIG. 5A is a diagram illustrating the structure of a second conductive layer and a third conductive layer in two adjacent pixel driving circuits in an array substrate depicted in FIG. 3A.

FIG. 5B is a diagram illustrating the structure of a second conductive layer, a third conductive layer, and a first signal line layer of two adjacent pixel driving circuits in an array substrate depicted in FIG. 3A.

FIG. 5C is a diagram illustrating the structure of a second conductive layer and a first signal line layer of two adjacent pixel driving circuits in an array substrate depicted in FIG. 3A.

FIG. 5D is a diagram illustrating the structure of a second conductive layer and a second semiconductor layer of two adjacent pixel driving circuits in an array substrate depicted in FIG. 3A.

FIG. 5E is a diagram illustrating the structure of a first semiconductor material layer and a light shield layer of two adjacent pixel driving circuits in an array substrate depicted in FIG. 3A.

FIG. 5F is a diagram illustrating the structure of a first conductive layer and a light shield layer of two adjacent pixel driving circuits in an array substrate depicted in FIG. 3A.

FIG. 5G is a diagram illustrating the structure of a second conductive layer and a light shield layer of two adjacent pixel driving circuits in an array substrate depicted in FIG. 3A.

FIG. 5H is a diagram illustrating the structure of a second semiconductor material layer and a second signal line layer of two adjacent pixel driving circuits in an array substrate depicted in FIG. 3A.

FIG. 5I is a diagram illustrating the structure of a first signal line layer and a second signal line layer of two adjacent pixel driving circuits in an array substrate depicted in FIG. 3A.

FIG. 6A is a diagram illustrating the structure of a first semiconductor material layer and a second conductive layer of two adjacent pixel driving circuits in an array substrate depicted in FIG. 3A.

FIG. 6B is a zoom-in view of a region comprising a second node portion in an array substrate in some embodiments according to the present disclosure.

FIG. 6C illustrates the structure of a second capacitor electrode in some embodiments according to the present disclosure.

FIG. 7 is a schematic diagram illustrating a display area and a peripheral area in an array substrate in some embodiments according to the present disclosure.

FIG. 8 illustrates the structure of a corner region in a first sub-area of an array substrate in some embodiments according to the present disclosure.

FIG. 9 illustrates the structure of a second signal line layer in a display area in an array substrate in some embodiments according to the present disclosure.

### DETAILED DESCRIPTION

The disclosure will now be described more specifically with reference to the following embodiments. It is to be noted that the following descriptions of some embodiments are presented herein for purpose of illustration and description only. It is not intended to be exhaustive or to be limited to the precise form disclosed.

The present disclosure provides, inter alia, an array substrate and a display apparatus that substantially obviate one or more of the problems due to limitations and disadvantages of the related art. In one aspect, the present disclosure provides an array substrate. In some embodiments, the array substrate includes a first adjacent data line and a second adjacent data line extending along a first direction. Optionally, the first adjacent data line and the second adjacent data line extending from a same inter-column region between a first column of pixel driving circuit and a second column of pixel driving circuit in a display area into a boundary area between the first column of pixel driving circuit and a peripheral area. Optionally, in the boundary area, the first adjacent data line and the second adjacent data line are in a same layer.

Various appropriate pixel driving circuits may be used in the present array substrate. Examples of appropriate driving circuits include 3TIC. 2TIC, 4TIC, 4T2C, 5T2C, 6TIC, 7TIC. 7T2C, 8TIC, and 8T2C. In some embodiments, the respective one of the plurality of pixel driving circuits is an 7TIC driving circuit. Various appropriate light emitting elements may be used in the present array substrate. Examples of appropriate light emitting elements include organic light emitting diodes, quantum dots light emitting diodes, and micro light emitting diodes. Optionally, the light emitting element is micro light emitting diode. Optionally, the light emitting element is an organic light emitting diode including an organic light emitting layer.

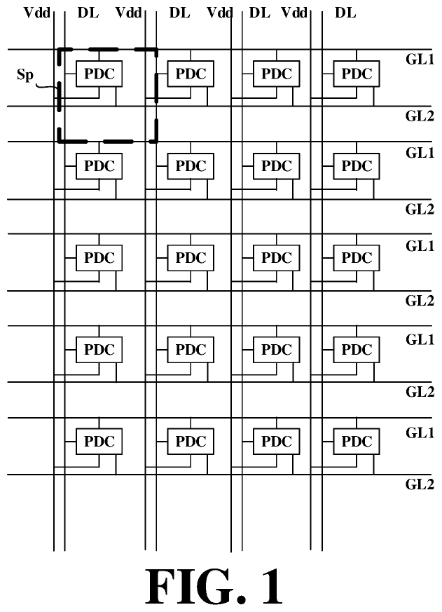

FIG. 1 is a plan view of an array substrate in some embodiments according to the present disclosure. Referring to FIG. 1, the array substrate includes an array of subpixels Sp. Each subpixel includes an electronic component, e.g., a light emitting element. In one example, the light emitting element is driven by a respective pixel driving circuit PDC. The array substrate includes a plurality of first gate lines GL1, a plurality of second gate lines GL2, a plurality of data lines DL, a plurality of voltage supply line Vdd, and a respective second voltage supply line (e.g., a low voltage supply line Vss). Light emission in a respective subpixel sp is driven by a respective pixel driving circuit PDC. In one example, a high voltage signal (e.g., a VDD signal) is input, through the respective high voltage supply line of the plurality of voltage supply line Vdd, to the respective pixel driving circuit PDC connected to an anode of the light emitting element; a low voltage signal (e.g., a VSS signal) is input, through a low voltage supply line Vss, to a cathode of the light emitting element. A voltage difference between the high voltage signal (e.g., the VDD signal) and the low voltage signal (e.g., the VSS signal) is a driving voltage ΔV that drives light emission in the light emitting element.

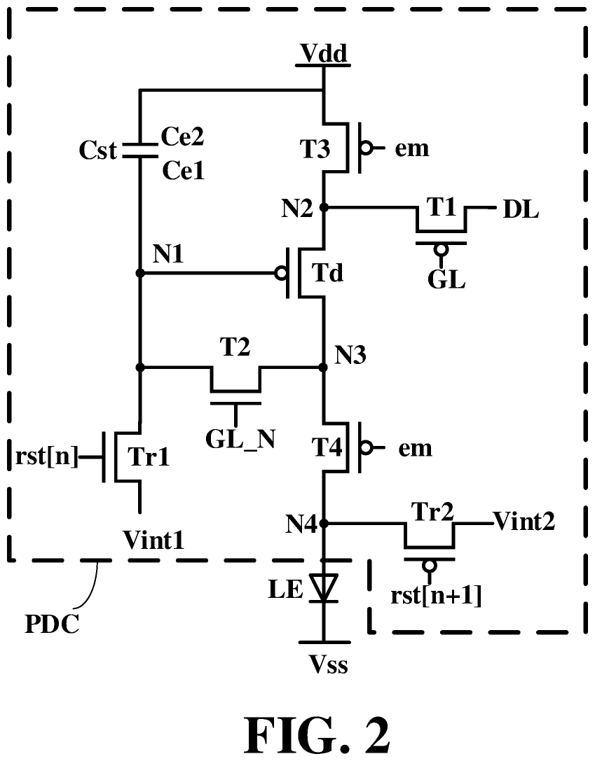

FIG. 2 is a circuit diagram illustrating the structure of a pixel driving circuit in some embodiments according to the present disclosure. Referring to FIG. 2, in some embodiments, the pixel driving circuit includes a driving transistor Td; a storage capacitor Cst having a first capacitor electrode Ce1 and a second capacitor electrode Ce2; a first transistor T1 having a gate electrode connected to a respective first gate line GL_P of a plurality of first gate lines, a first electrode connected to a respective data line DL of a plurality of data lines, and a second electrode connected to a first electrode of the driving transistor Td; a second transistor T2 having a gate electrode connected to the respective second gate line GL_N of a plurality of second gate lines, a first electrode connected to the first capacitor electrode Ce1 of the storage capacitor Cst and a second electrode of a first reset transistor, and a second electrode connected to the second electrode of the driving transistor Td and a first electrode of a fourth transistor T4; a third transistor T3 having a gate electrode connected to a respective light emitting control signal line em of a plurality of light emitting control signal lines, a first electrode connected to a respective voltage supply line Vdd of a plurality of voltage supply lines and a second capacitor electrode Ce2 of the storage capacitor, and a second electrode connected to the first electrode of the driving transistor Td and the second electrode of the first transistor T1; a fourth transistor T4 having a gate electrode connected to the respective light emitting control signal line em, a first electrode connected to the second electrode of the driving transistor Td and the second electrode of the second transistor T2, and a second electrode connected to an anode of a respective light emitting element LE; a first reset transistor Tr1 having a gate electrode connected to a respective reset control signal line rst[n] in a present stage of a plurality of reset control signal lines, a first electrode connected to a respective first reset signal line Vint1 of a plurality of first reset signal lines, and a second electrode connected to the first electrode of the second transistor T2, the gate electrode of the driving transistor Td, and the first capacitor electrode Ce1 of the storage capacitor Cst; a second reset transistor Tr2 having a gate electrode connected to a respective reset control signal line rst(n+1) in a next stage of a plurality of reset control signal lines, a first electrode connected to a respective second reset signal line Vint2 of a plurality of second reset signal lines, and a second electrode connected to the anode of the respective light emitting element LE and the second electrode of the fourth transistor T4. The second capacitor electrode Ce2 is connected to the respective voltage supply line and the first electrode of the third transistor T3.

The pixel driving circuit further include a first node N1, a second node N2, a third node N3, and a fourth node N4. The first node N1 is connected to the gate electrode of the driving transistor Td, the first capacitor electrode Ce1, the first electrode of the second transistor T2, and the second electrode of the first reset transistor Tr1. The second node N2 is connected to the second electrode of the third transistor T3, the second electrode of the first transistor T1, and the first electrode of the driving transistor Td. The third node N3 is connected to the second electrode of the driving transistor Td, the second electrode of the second transistor T2, and the first electrode of the fourth transistor T4. The fourth node N4 is connected to the second electrode of the fourth transistor T4, the second electrode of the second reset transistor Tr2, and the anode of the light emitting element LE.

The array substrate in some embodiments includes a plurality of subpixels. In some embodiments, the plurality of subpixels includes a respective first subpixel, a respective second subpixel, a respective third subpixel, and a respective fourth subpixel. Optionally, a respective pixel of the array substrate includes the respective first subpixel, the respective second subpixel, the respective third subpixel, and the respective fourth subpixel. The plurality of subpixels in the array substrate are arranged in an array. In one example, the array of the plurality of subpixels includes a S1-S2-S3-S4 format repeating array, in which S1 stands for the respective first subpixel. S2 stands for the respective second subpixel, S3 stands for the respective third subpixel, and S4 stands for the respective fourth subpixel. In another example, the S1-S2-S3-S4 format is a C1-C2-C3-C4 format, in which C1 stands for the respective first subpixel of a first color, C2 stands for the respective second subpixel of a second color, C3 stands for the respective third subpixel of a third color, and C4 stands for the respective fourth subpixel of a fourth color. In another example, the S1-S2-S3-S4 format is a C1-C2-C3-C2′ format, in which C1 stands for the respective first subpixel of a first color, C2 stands for the respective second subpixel of a second color, C3 stands for the respective third subpixel of a third color, and C2′ stands for the respective fourth subpixel of the second color. In another example, the C1-C2-C3-C2′ format is a R-G-B-G format, in which the respective first subpixel is a red subpixel, the respective second subpixel is a green subpixel, the respective third subpixel is a blue subpixel, and the respective fourth subpixel is a green subpixel.

In some embodiments, a minimum repeating unit of the plurality of subpixels of the array substrate includes the respective first subpixel, the respective second subpixel, the respective third subpixel, and the respective fourth subpixel. Optionally, each of the respective first subpixel, the respective second subpixel, the respective third subpixel, and the respective fourth subpixel, includes the first transistor T1, the second transistor T2, the third transistor T3, the fourth transistor T4, the first reset transistor Tr1, the second reset transistor Tr2, and the driving transistor Td.

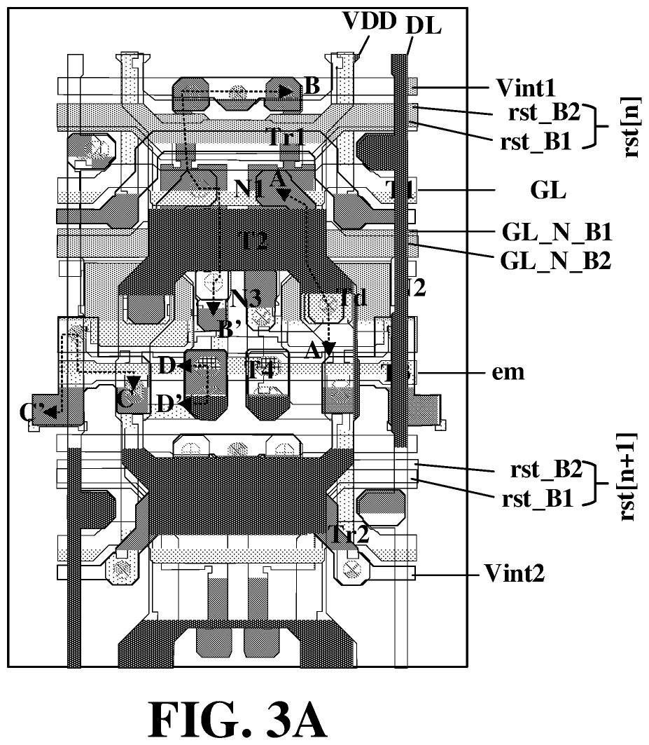

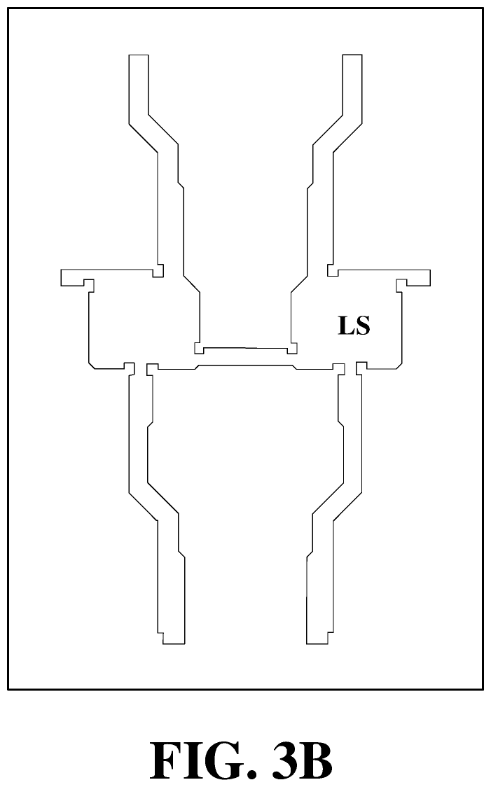

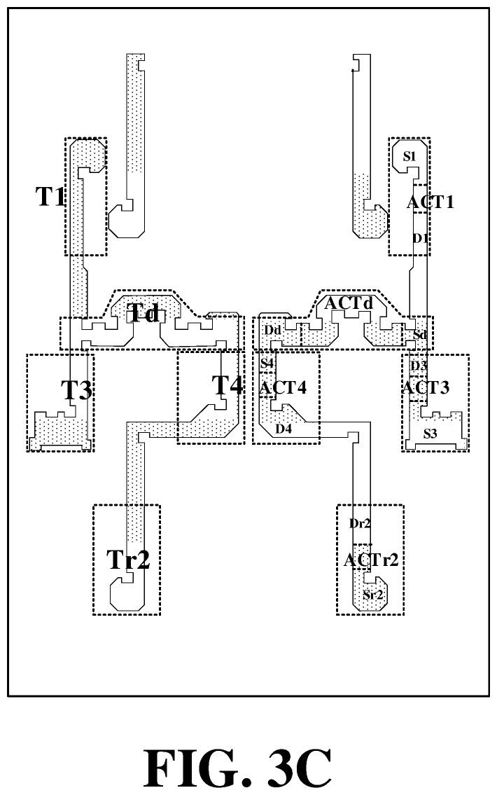

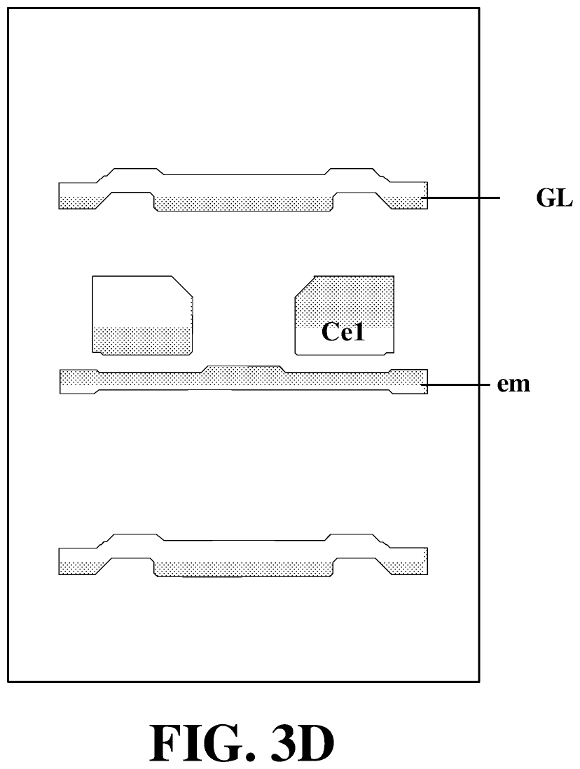

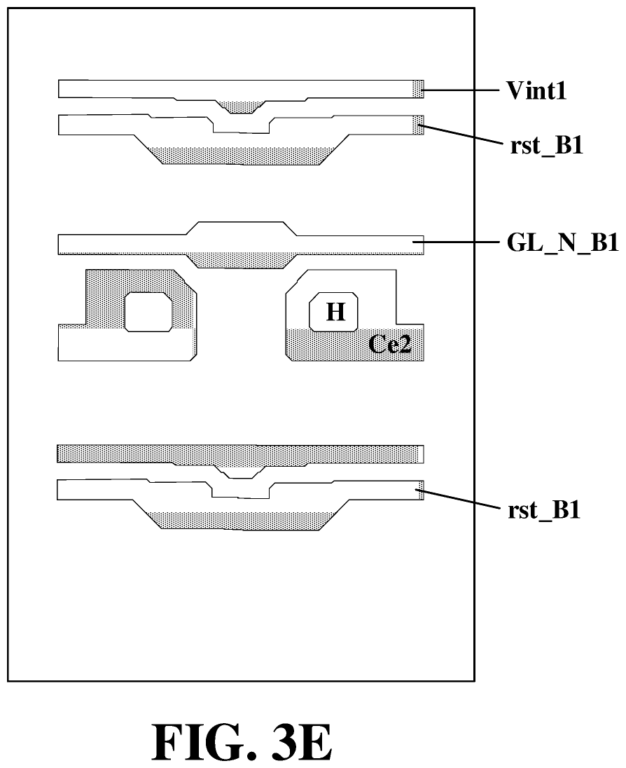

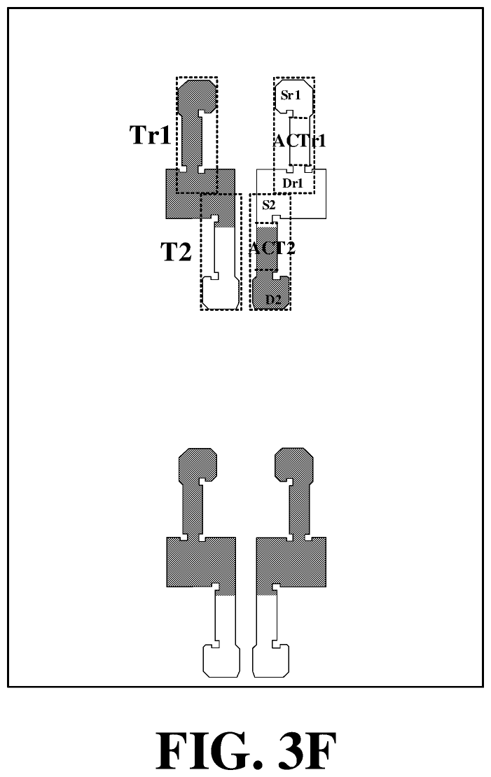

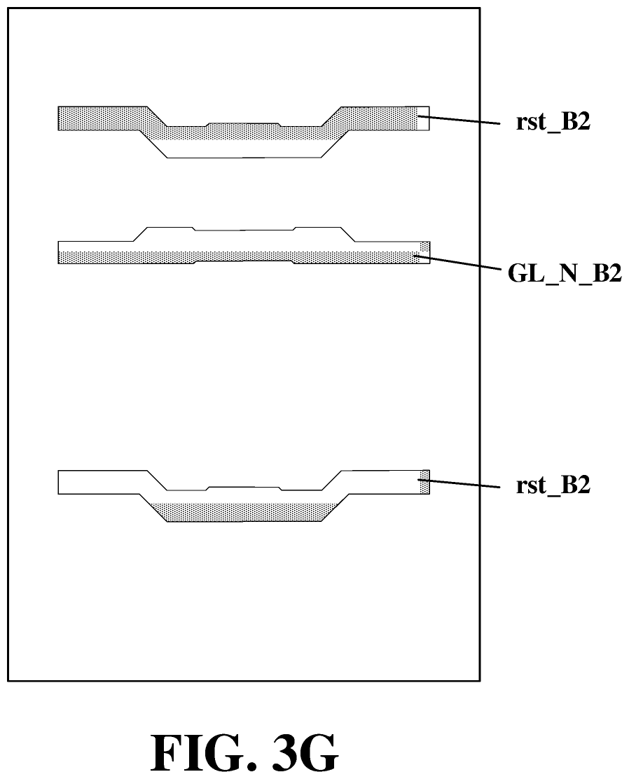

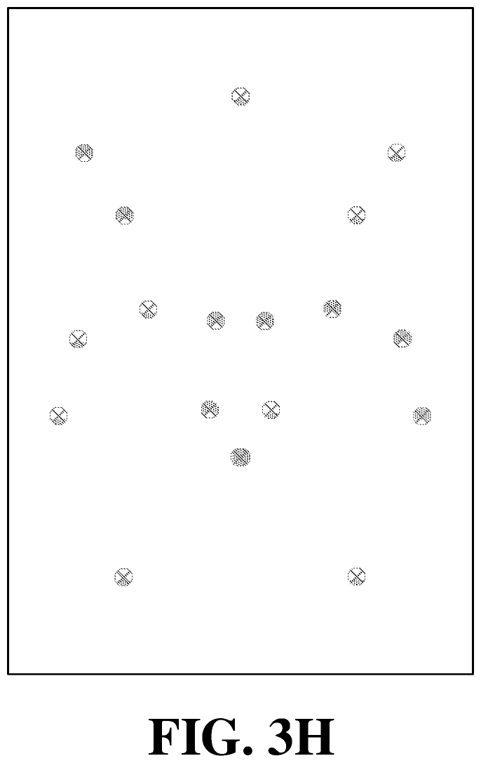

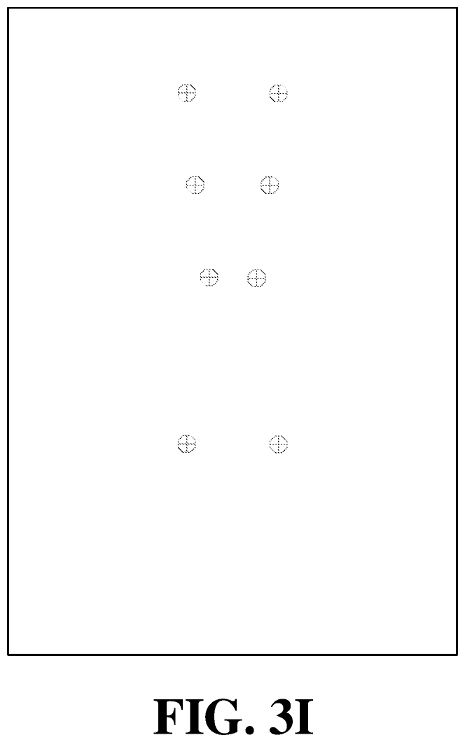

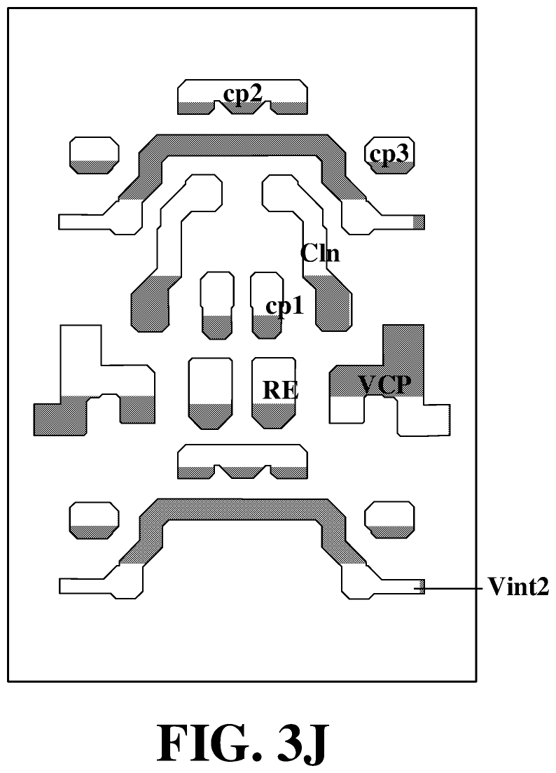

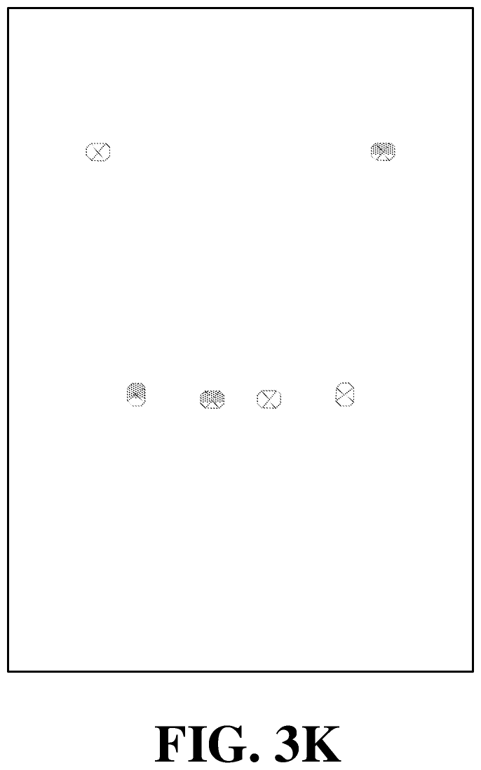

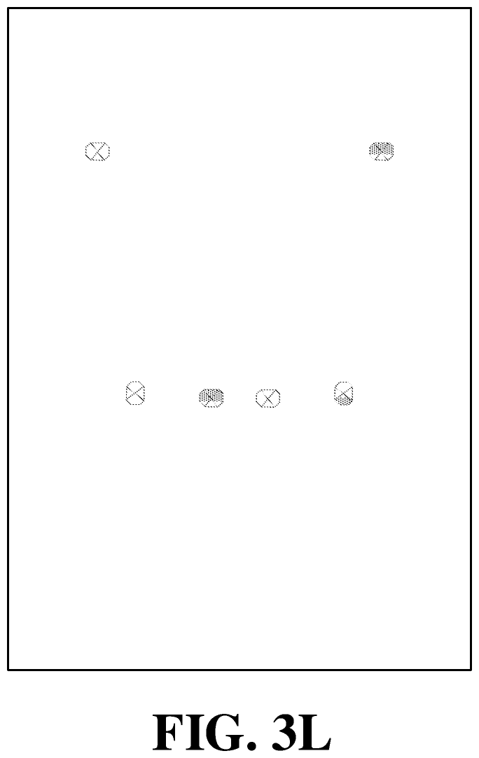

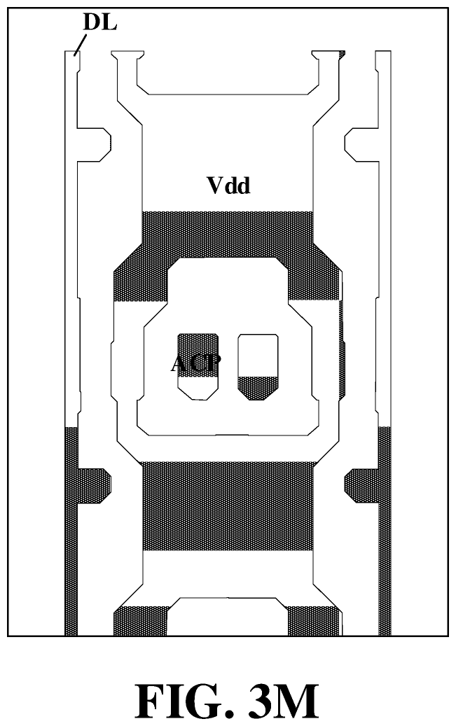

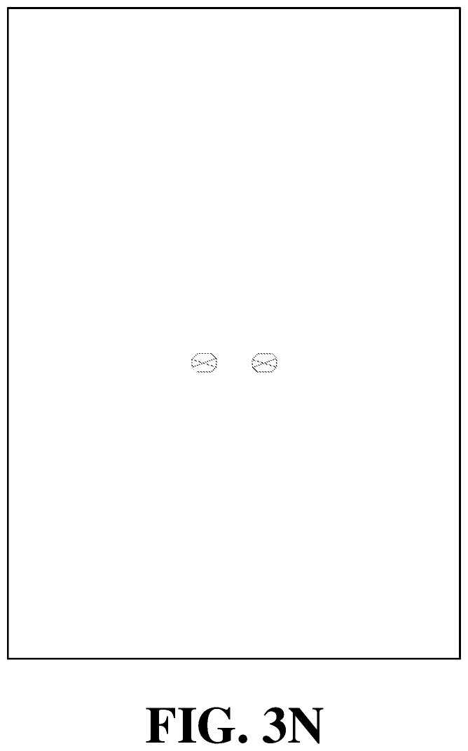

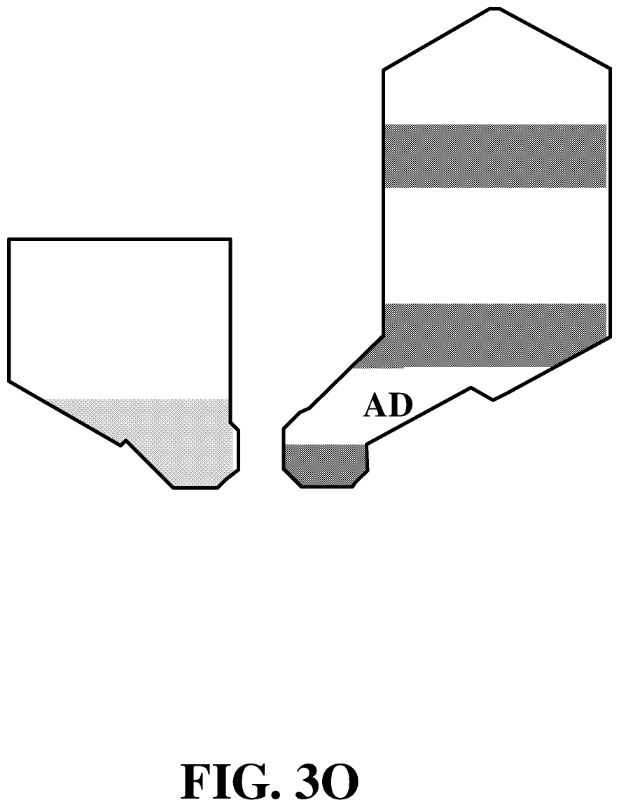

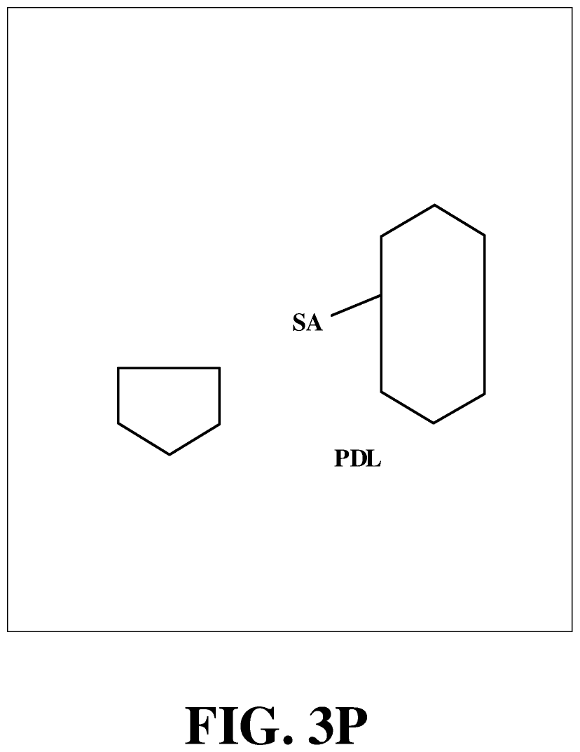

FIG. 3A is a diagram illustrating the structure of two adjacent pixel driving circuits in a same stage in an array substrate in some embodiments according to the present disclosure. FIG. 3B is a diagram illustrating the structure of a light shield layer of two adjacent pixel driving circuits in an array substrate depicted in FIG. 3A. FIG. 3C is a diagram illustrating the structure of a first semiconductor material layer of two adjacent pixel driving circuits in an array substrate depicted in FIG. 3A. FIG. 3D is a diagram illustrating the structure of a first conductive layer of two adjacent pixel driving circuits in an array substrate depicted in FIG. 3A. FIG. 3E is a diagram illustrating the structure of a second conductive layer of two adjacent pixel driving circuits in an array substrate depicted in FIG. 3A. FIG. 3F is a diagram illustrating the structure of a second semiconductor material layer of two adjacent pixel driving circuits in an array substrate depicted in FIG. 3A. FIG. 3G is a diagram illustrating the structure of a third conductive layer of two adjacent pixel driving circuits in an array substrate depicted in FIG. 3A. FIG. 3H is a diagram illustrating vias extending through a passivation layer, a second inter-layer dielectric layer, a first inter-layer dielectric layer, an insulating layer and a gate insulating layer in an array substrate depicted in FIG. 3A. FIG. 3I is a diagram illustrating vias extending through a passivation layer and a second inter-layer dielectric layer in an array substrate depicted in FIG. 3A. FIG. 3J is a diagram illustrating the structure of a first signal line layer of two adjacent pixel driving circuits in an array substrate depicted in FIG. 3A. FIG. 3K is a diagram illustrating vias extending through a first planarization layer in an array substrate depicted in FIG. 3A. FIG. 3L is a diagram illustrating vias extending through a passivation layer, a second inter-layer dielectric layer, a first inter-layer dielectric layer, an insulating layer and a gate insulating layer in an array substrate depicted in FIG. 3A. FIG. 3M is a diagram illustrating the structure of a second signal line layer of two adjacent pixel driving circuits in an array substrate depicted in FIG. 3A. FIG. 3N is a diagram illustrating vias extending through a second planarization layer in an array substrate depicted in FIG. 3A. FIG. 3O is a diagram illustrating the structure of an anode layer of two adjacent pixel driving circuits in an array substrate depicted in FIG. 3A. FIG. 3P is a diagram illustrating the structure of a pixel definition layer of two adjacent pixel driving circuits in an array substrate depicted in FIG. 3A.

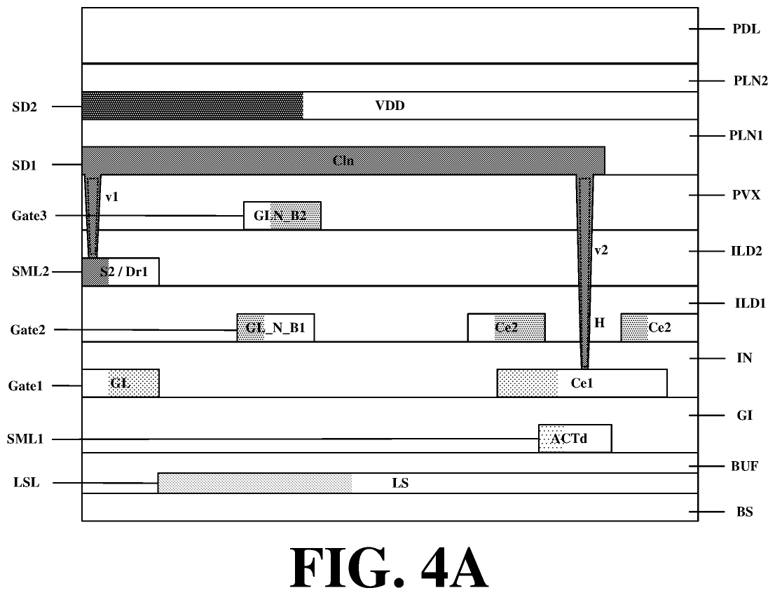

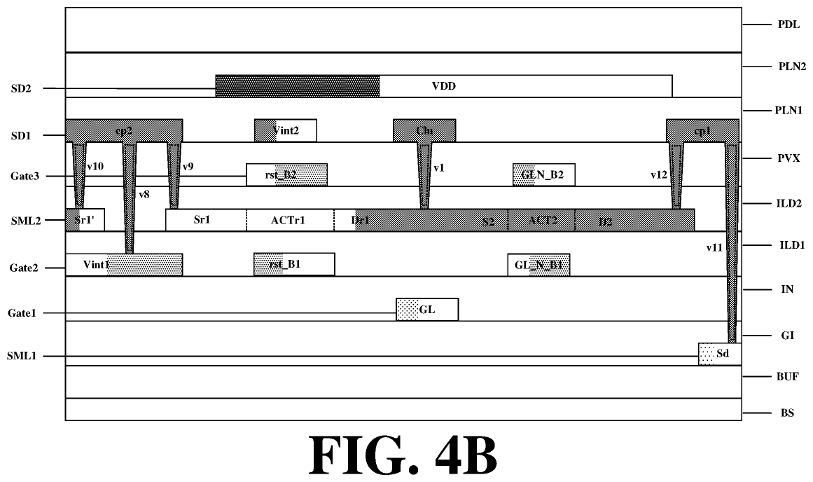

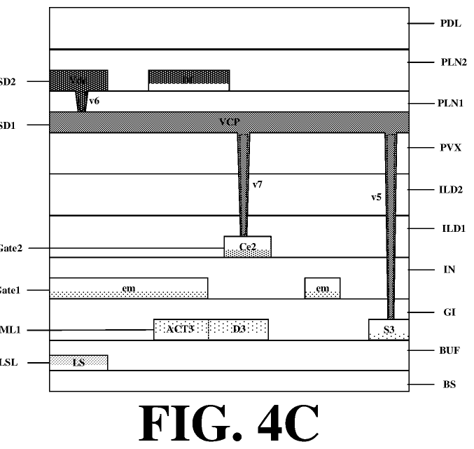

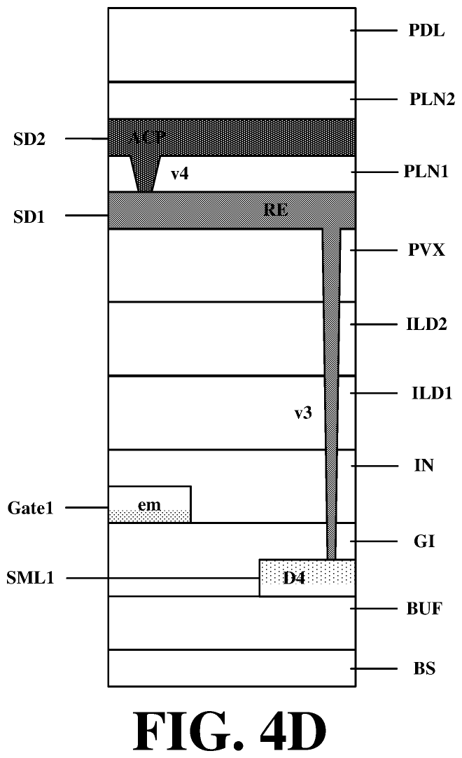

FIG. 4A is a cross-sectional view along an A-A′ line in FIG. 3A. FIG. 4B is a cross-sectional view along a B-B′ line in FIG. 3A. FIG. 4C is a cross-sectional view along a C-C′ line in FIG. 3A.

Referring to FIG. 3A to FIG. 3P, and FIG. 4A to FIG. 4C, in some embodiments, corresponding layers of a first pixel driving circuit and corresponding layers of a second pixel driving circuit directly adjacent to each other and in the present stage have a substantially mirror symmetry with respect to each other, e.g., about a plane perpendicular to a main surface of the array substrate and substantially parallel to the data lines in FIG. 3A.

Referring to FIG. 3A to FIG. 3P, and FIG. 4A to FIG. 4C, in some embodiments, the array substrate includes a base substrate BS, a light shield layer LSL on the base substrate BS, a buffer layer BUF on a side of the light shield layer LSL away from the base substrate BS, a first semiconductor material layer SML1 on a side of the buffer layer BUF away from the base substrate BS, a gate insulating layer GI on a side of the first semiconductor material layer SML1 away from the base substrate BS, a first conductive layer Gate1 on a side of the gate insulating layer GI away from the first semiconductor material layer SML1, an insulating layer IN on a side of the first conductive layer Gate1 away from the gate insulating layer GI, a second conductive layer Gate2 on a side of the insulating layer IN away from the first conductive layer Gate1, a first inter-layer dielectric layer ILD1 on a side of the second conductive layer Gate2 away from the insulating layer IN, a second semiconductor material layer SML2 on a side of the first inter-layer dielectric layer ILD1 away from the second conductive layer Gate2, a second inter-layer dielectric layer ILD2 on a side of the second semiconductor material layer SML2 away from the first inter-layer dielectric layer ILD1, a third conductive layer Gate3 on a side of the second inter-layer dielectric layer ILD2 away from the second semiconductor material layer SML2, a passivation layer PVX on a side of the third conductive layer Gate3 away from the second inter-layer dielectric layer ILD2, a first signal line layer SD1 on a side of the passivation layer PVX away from the third conductive layer Gate3, a first planarization layer PLN1 on a side of the first signal line layer SD1 away from the passivation layer PVX, a second signal line layer SD2 on a side of the first planarization layer PLN1 away from the first signal line layer SD1, a second planarization layer PLN2 on a side of the second signal line layer SD2 away from the first planarization layer PLN1, and a pixel definition layer PDL on a side of the second planarization layer PLN2 away from the second signal line layer SD2.

Referring to FIG. 2, FIG. 3A, FIG. 3C, and FIG. 4A to FIG. 4C, in some embodiments, the light shield layer LSL includes a light shield LS. Various appropriate materials and various appropriate fabricating methods may be used for making the light shield layer LSL. For example, a metallic material may be deposited on the substrate by a plasma-enhanced chemical vapor deposition (PECVD) process. Examples of appropriate metallic materials for making the light shield layer LSL include, but are not limited to, aluminum, chromium, tungsten, titanium, tantalum, molybdenum, copper, and alloys or laminates containing the same.

Referring to FIG. 2, FIG. 3A, FIG. 3C, and FIG. 4A to FIG. 4C, in some embodiments, the first semiconductor material layer SML1 includes at least active layers of multiple transistors of the pixel driving circuit, including the first transistor T1, the third transistor T3, the fourth transistor T4, the second reset transistor Tr2, and the driving transistor Td. Optionally, the first semiconductor material layer SML1 further includes at least respective portions of first electrodes of multiple transistors of the pixel driving circuit, including the first transistor T1, the third transistor T3, the fourth transistor T4, the second reset transistor Tr2, and the driving transistor Td. Optionally, the first semiconductor material layer SML1 further includes at least respective portions of second electrodes of multiple transistors of the pixel driving circuit, including the first transistor T1, the third transistor T3, the fourth transistor T4, the second reset transistor Tr2, and the driving transistor Td. Optionally, the first semiconductor material layer SML1 includes active layers, first electrodes, and second electrodes of multiple transistors of the pixel driving circuit, including the first transistor T1, the third transistor T3, the fourth transistor T4, the second reset transistor Tr2, and the driving transistor Td. Various appropriate semiconductor materials may be used for making the first semiconductor material layer SML1. Examples of the semiconductor materials for making the first semiconductor material layer SML1 include silicon-based semiconductor materials such as polycrystalline silicon, single-crystal silicon, and amorphous silicon.

In FIG. 3C, the pixel driving circuit on the left is annotated with labels indicating components of each of multiple transistors (T1, T3, T4, Tr2, and Td) in the pixel driving circuit. For example, the first transistor T1 includes an active layer ACT1, a first electrode S1, and a second electrode D1. The third transistor T3 includes an active layer ACT3, a first electrode S3, and a second electrode D3. The fourth transistor T4 includes an active layer ACT4, a first electrode S4, and a second electrode D4. The second reset transistor Tr2 includes an active layer ACTr2, a first electrode Sr2, and a second electrode Dr2. The driving transistor Td includes an active layer ACTd, a first electrode Sd, and a second electrode Dd.

Optionally, the active layers (ACT1, ACT3, ACT4, ACTr2, and ACTd), the first electrodes (S1, S3, S4, Sr2, and Sd), and the second electrodes (D1, D3, D4, Dr2, and Dd) of the respective transistors (T1, T3, T4, Tr2, and Td) are in a same layer.

In some embodiments, the active layers (ACT1, ACT3, ACT4, ACTr2, and ACTd), the first electrodes (S1, S3, S4, Sr2, and Sd), and the second electrodes (D1, D3, D4, Dr2, and Dd) of the respective transistors (T1, T3, T4, Tr2, and Td) in the pixel driving circuit are parts of a unitary structure.

Referring to FIG. 2, FIG. 3A, FIG. 3D, and FIG. 4A to FIG. 4C, in some embodiments, the first conductive layer Gate1 in some embodiments includes a plurality of first gate lines (e.g., a respective first gate line GL), a plurality of light emitting control signal lines (e.g., a respective light emitting control signal line em), and a first capacitor electrode Ce1 of the storage capacitor Cst. Various appropriate electrode materials and various appropriate fabricating methods may be used to make the first conductive layer Gate1. For example, a conductive material may be deposited on the substrate by a plasma-enhanced chemical vapor deposition (PECVD) process and patterned. Examples of appropriate conductive materials for making the first conductive layer Gate1 include, but are not limited to, aluminum, copper, molybdenum, chromium, aluminum copper alloy, copper molybdenum alloy, molybdenum aluminum alloy, aluminum chromium alloy, copper chromium alloy, molybdenum chromium alloy, copper molybdenum aluminum alloy, and the like. Optionally, the plurality of first gate lines (e.g., the respective first gate line GL), the plurality of light emitting control signal lines (e.g., the respective light emitting control signal line em), and the first capacitor electrode Ce1 of the storage capacitor Cst are in a same layer.

As used herein, the term “same layer” refers to the relationship between the layers simultaneously formed in the same step. In one example, the plurality of first gate lines and the first capacitor electrode Ce1 are in a same layer when they are formed as a result of one or more steps of a same patterning process performed in a same layer of material. In another example, the plurality of first gate lines and the first capacitor electrode Ce1 can be formed in a same layer by simultaneously performing the step of forming the plurality of first gate lines, and the step of forming the first capacitor electrode Ce1. The term “same layer” does not always mean that the thickness of the layer or the height of the layer in a cross-sectional view is the same.

Referring to FIG. 2, FIG. 3A, FIG. 3E, and FIG. 4A to FIG. 4C, in some embodiments, the second conductive layer Gate2 in some embodiments includes at least portions of a plurality of second gate lines (e.g., a first branch GL_N_B1), at least portions of a plurality of reset control signal lines (e.g., a first branch rst_B1 of a respective reset control signal line rstn in a present stage, a first branch rst_B1 of a respective reset control signal line rst(n+1) in a next stage), a plurality of first reset signal lines (e.g., a respective first reset signal line Vint1), and a second capacitor electrode Ce2 of the storage capacitor Cst. Various appropriate electrode materials and various appropriate fabricating methods may be used to make the second conductive layer Gate2. For example, a conductive material may be deposited on the substrate by a plasma-enhanced chemical vapor deposition (PECVD) process and patterned. Examples of appropriate conductive materials for making the second conductive layer Gate2 include, but are not limited to, aluminum, copper, molybdenum, chromium, aluminum copper alloy, copper molybdenum alloy, molybdenum aluminum alloy, aluminum chromium alloy, copper chromium alloy, molybdenum chromium alloy, copper molybdenum aluminum alloy, and the like. Optionally, the at least portions of the plurality of second gate lines (e.g., the first branch GL_N_B1), the at least portions of the plurality of reset control signal lines (e.g., the first branch rst_B1 of the respective reset control signal line rstn in a present stage, the first branch rst_B1 of the respective reset control signal line rst(n+1) in a next stage), the plurality of first reset signal lines (e.g., the respective first reset signal line Vint1), and the second capacitor electrode Ce2 of the storage capacitor Cst are in a same layer.

Referring to FIG. 2, FIG. 3A, FIG. 3F, and FIG. 4A to FIG. 4C, in some embodiments, the second semiconductor material layer SML2 includes at least an active layer of the second transistor T2 and at least an active layer of the first reset transistor Tr1. Optionally, the second semiconductor material layer SML2 further includes at least a portion of a first electrode of the second transistor T2 and at least a portion of a first electrode of the first reset transistor Tr1. Optionally, the second semiconductor material layer SML2 further includes at least a portion of a second electrode of the second transistor T2 and at least a portion of a second electrode of the first reset transistor Tr1. Optionally, the second semiconductor material layer SML2 includes the active layer, the first electrode, and the second electrode of the second transistor T2, and the active layer, the first electrode, and the second electrode of the first reset transistor Tr1. In the present array substrate, at least the active layer of the second transistor T2 and at least the active layer of the first reset transistor Tr1 are in a layer different from at least the active layers of other transistors of the pixel driving circuit. Various appropriate semiconductor materials may be used for making the second semiconductor material layer SML2. Examples of the semiconductor materials for making the second semiconductor material layer SML2 include metal oxide-based semiconductor material such as indium gallium zinc oxide and metal oxynitride-based semiconductor materials such as zinc oxynitride.

In FIG. 3F, the pixel driving circuit on the right is annotated with labels indicating components of the second transistor T2 and the first reset transistor Tr1 in the pixel driving circuit. For example, the second transistor T2 includes an active layer ACT2, a first electrode S2, and a second electrode D2; the first reset transistor Tr1 includes an active layer ACTr1, a first electrode Sr1, and a second electrode Dr1. Optionally, the active layer ACT2, the first electrode S2, the second electrode D2, the active layer ACTr1, the first electrode Sr1, and the second electrode Dr1 are in a same layer. Referring to FIG. 3A, FIG. 3C, FIG. 3F, and FIG. 4A to FIG. 4C, the active layer ACTd of the driving transistor Td and active layers of the second transistor T2 and the first reset transistor Tr1 are spaced apart from each other by the gate insulating layer GI, the insulating layer IN, and the first inter-layer dielectric layer ILD1. The active layer ACTd of the driving transistor Td includes a first semiconductor material; and the active layers of the second transistor T2 and the first reset transistor Tr1 include a second semiconductor material different from the first semiconductor material.

Referring to FIG. 2, FIG. 3A, FIG. 3G, and FIG. 4A to FIG. 4C, in some embodiments, the third conductive layer Gate3 includes at least portions of a plurality of second gate lines (e.g., a second branch GL_N_B2), and at least portions of a plurality of reset control signal lines (e.g., a second branch rst_B2 of a respective reset control signal line rstn in a present stage, a second branch rst_B2 of a respective reset control signal line rst(n+1) in a next stage). Various appropriate electrode materials and various appropriate fabricating methods may be used to make the third conductive layer Gate3. For example, a conductive material may be deposited on the substrate by a plasma-enhanced chemical vapor deposition (PECVD) process and patterned. Examples of appropriate conductive materials for making the third conductive layer Gate3 include, but are not limited to, aluminum, copper, molybdenum, chromium, aluminum copper alloy, copper molybdenum alloy, molybdenum aluminum alloy, aluminum chromium alloy, copper chromium alloy, molybdenum chromium alloy, copper molybdenum aluminum alloy, and the like. Optionally, the at least portions of a plurality of second gate lines (e.g., the second branch GL_N_B2), and the at least portions of the plurality of reset control signal lines (e.g., the second branch rst_B2 of the respective reset control signal line rstn in a present stage, the second branch rst_B2 of the respective reset control signal line rst(n+1) in a next stage) are in a same layer.

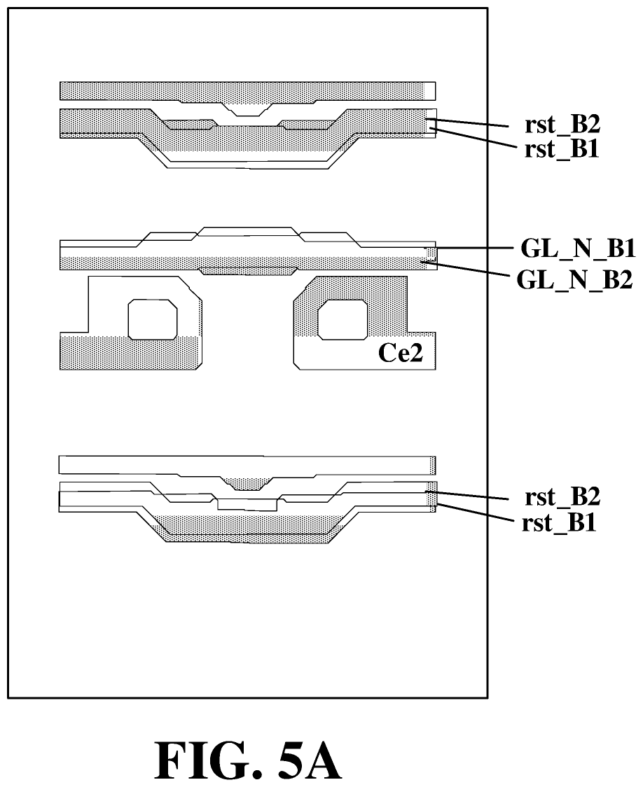

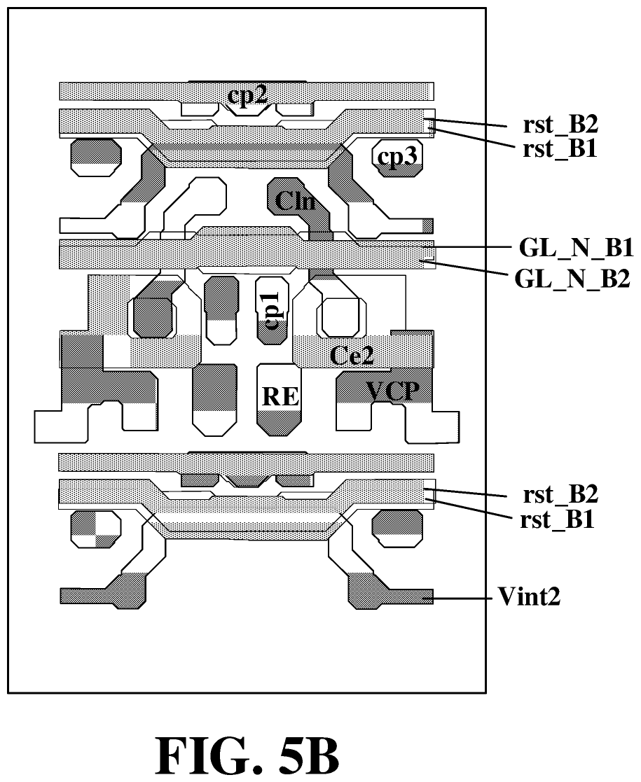

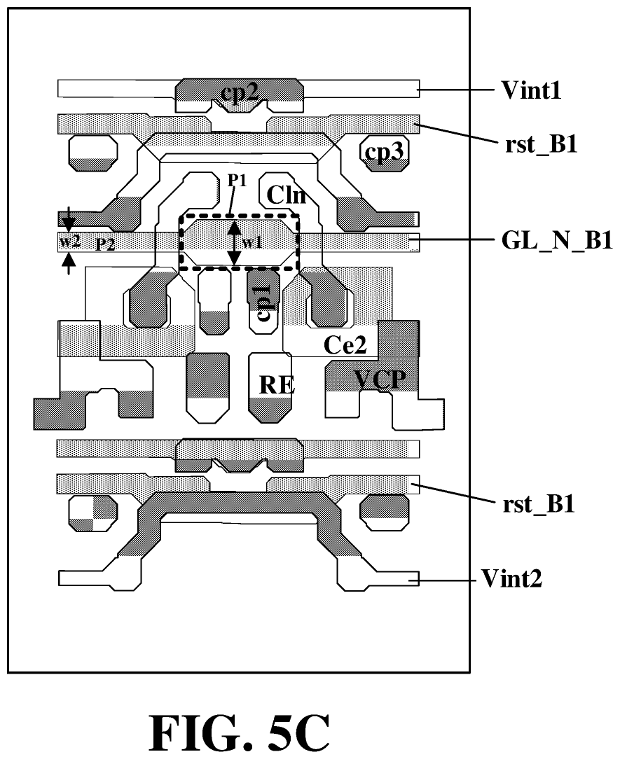

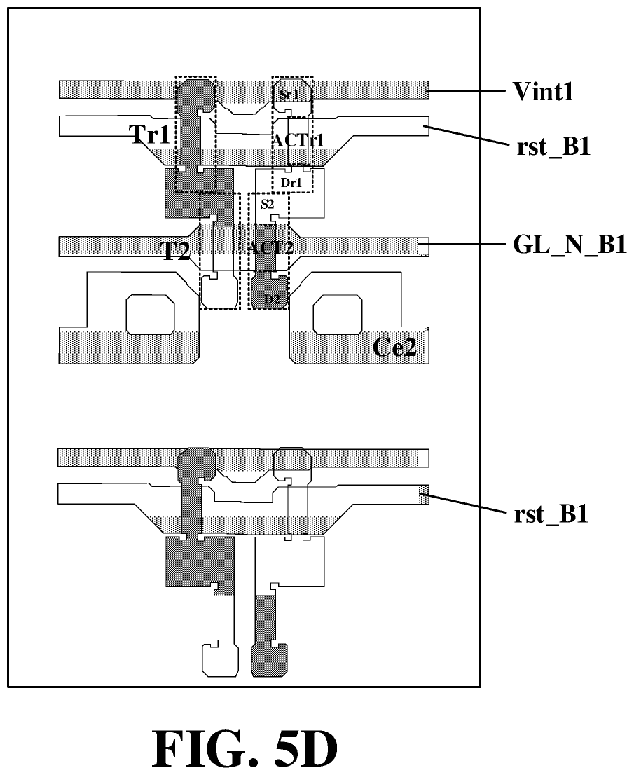

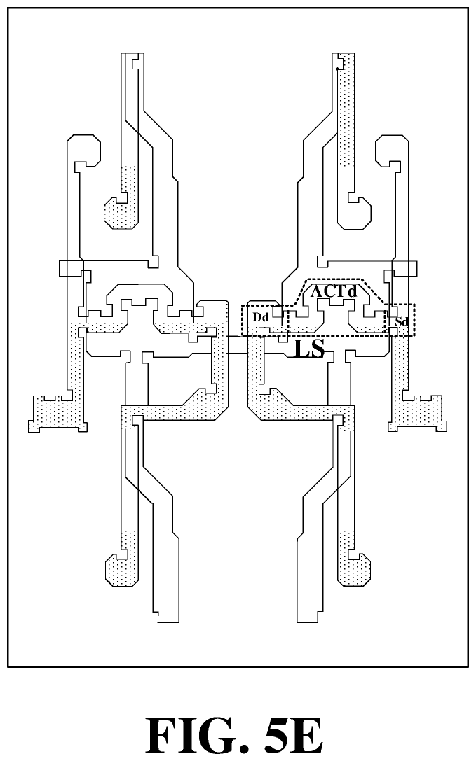

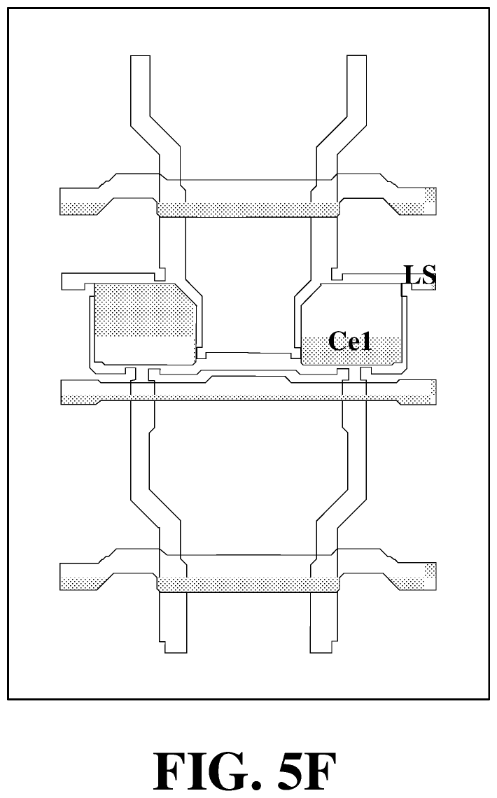

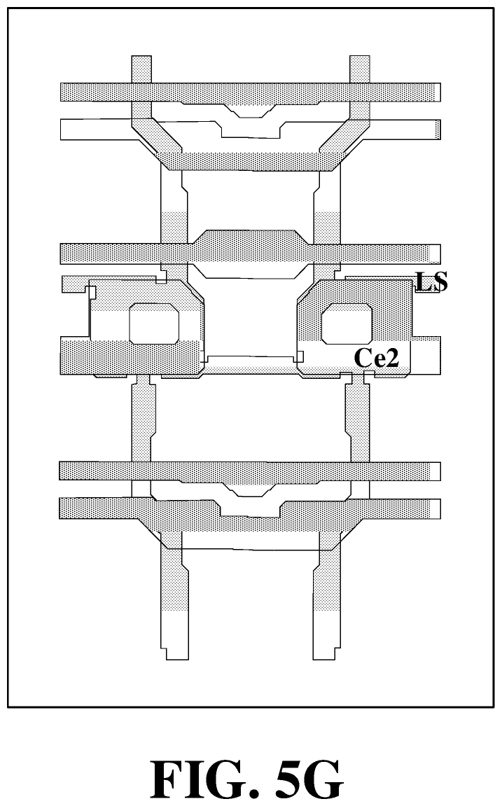

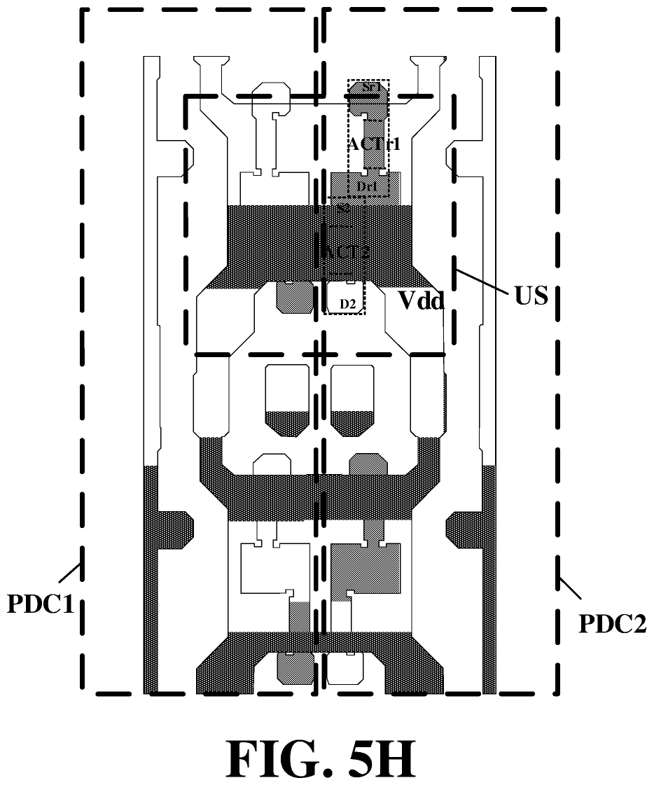

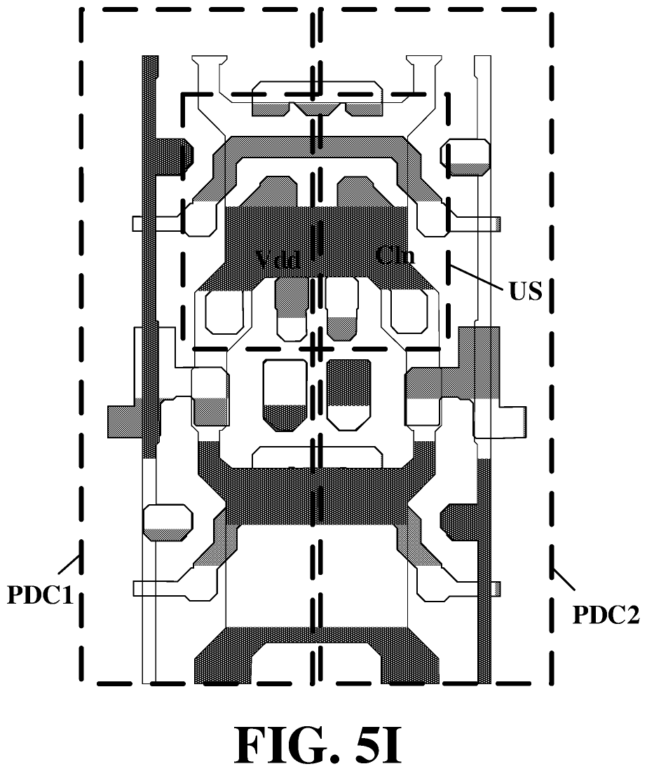

FIG. 5A is a diagram illustrating the structure of a second conductive layer and a third conductive layer in two adjacent pixel driving circuits in an array substrate depicted in FIG. 3A. In some embodiments, referring to FIG. 5A, the respective second gate line GL_N includes the first branch GL_N_B1 and the second branch GL_N_B2 in two different layers. Optionally, the first branch GL_N_B1 is in the second conductive layer Gate2, and the second branch GL_N_B2 is in the third conductive layer Gate3. As shown in FIG. 3A, FIG. 4A, and FIG. 4B, in some embodiments, an orthographic projection of the first branch GL_N_B1 on a base substrate BS at least partially overlaps with an orthographic projection of the second branch GL_N_B2 on the base substrate BS.

In some embodiments, referring to FIG. 5A, the respective reset control signal line rstn includes the first branch rst_B1 and the second branch rst_B2 in two different layers. Optionally, the first branch rst_B1 is in the second conductive layer Gate2, and the second branch rst_B2 is in the third conductive layer Gate3. As shown in FIG. 3A, and FIG. 4B, in some embodiments, an orthographic projection of the first branch rst_B1 on a base substrate BS at least partially overlaps with an orthographic projection of the second branch rst_B2 on the base substrate BS.

Referring to FIG. 2, FIG. 3A, FIG. 3J, and FIG. 4A to FIG. 4C, in some embodiments, the first signal line layer SD1 includes a plurality of second reset signal lines (e.g., a respective second reset signal line Vint2), a node connecting line Cln, a first connecting pad cp1, a second connecting pad cp2, a third connecting pad cp3, a voltage connecting pad VCP, and a relay electrode RE. Various appropriate conductive materials and various appropriate fabricating methods may be used to make the first signal line layer SD1. For example, a conductive material may be deposited on the substrate by a plasma-enhanced chemical vapor deposition (PECVD) process and patterned. Examples of appropriate conductive materials for making the first signal line layer include, but are not limited to, aluminum, copper, molybdenum, chromium, aluminum copper alloy, copper molybdenum alloy, molybdenum aluminum alloy, aluminum chromium alloy, copper chromium alloy, molybdenum chromium alloy, copper molybdenum aluminum alloy, and the like. Optionally, the plurality of second reset signal lines (e.g., the respective second reset signal line Vint2), the node connecting line Cln, the first connecting pad cp1, the second connecting pad cp2, the third connecting pad cp3, the voltage connecting pad VCP, and the relay electrode RE are in a same layer. By having the plurality of first reset signal line Vint1 and the plurality of second reset signal lines Vint2, the first reset transistor Tr1 and the second reset transistor Tr2 can be separately connected to different reset signal lines. By having this unique structure, a reference voltage level at the anode of the respective light emitting element can be further stabilized, greatly enhancing brightness uniformity among different periods of a frame of image.

In some embodiments, the node connecting line Cln connects various components of the pixel driving circuit to the node N1. Referring to FIG. 4A, the node connecting line Cln connects the first electrode S2 of the second transistor T2 and the second electrode Dr1 of the first reset transistor Tr1 to the first capacitor electrode Ce1, which functions as a gate electrode of the driving transistor Td. The node connecting line Cln is connected to the first electrode S2 of the second transistor T2 and the second electrode Dr1 of the first reset transistor Tr1 through a first via v1 extending through the passivation layer PVX and the second inter-layer dielectric layer ILD2. The node connecting line Cln is connected to the first capacitor electrode Ce1 through a second via v2 extending through the passivation layer PVX, the second inter-layer dielectric layer ILD2, the first inter-layer dielectric layer ILD1, and the insulating layer IN.

Referring to FIG. 2, FIG. 3A, FIG. 3D, and FIG. 4A, in some embodiments, in a hole region H, a portion of the second capacitor electrode Ce2 is absent. Optionally, an orthographic projection of the second capacitor electrode Ce2 on a base substrate BS substantially covers an orthographic projection of the first capacitor electrode Ce1 on the base substrate BS except for a hole region H in which a portion of the second capacitor electrode Ce2 is absent. In one example, the orthographic projection of the second capacitor electrode Ce2 on the base substrate BS completely covers, with a margin, the orthographic projection of the first capacitor electrode Ce1 on the base substrate BS except for the hole region H in which a portion of the second capacitor electrode Ce2 is absent.

In some embodiments, referring to FIG. 3A, FIG. 3E, FIG. 3G, FIG. 3J, and FIG. 4A, the node connecting line Cln crosses over the respective second gate line GL_N. FIG. 5B is a diagram illustrating the structure of a second conductive layer, a third conductive layer, and a first signal line layer of two adjacent pixel driving circuits in an array substrate depicted in FIG. 3A. As shown in FIG. 5B, the node connecting line Cln crosses over the first branch GL_N_B1 in the second conductive layer Gate2, and the second branch GL_N_B2 in the third conductive layer Gate3.

FIG. 5C is a diagram illustrating the structure of a second conductive layer and a first signal line layer of two adjacent pixel driving circuits in an array substrate depicted in FIG. 3A. Referring to FIG. 5C, the first branch GL_N_B1 includes a first portion P1 in a region surrounded by node connecting lines respectively from two directly adjacent pixel driving circuits and in a same stage (e.g., the present stage) and first connecting pads respectively from the two directly adjacent pixel driving circuits and in the same stage (e.g., the present stage), and a second portion P2 outside the region surrounded by node connecting lines respectively from two directly adjacent pixel driving circuits and in a same stage (e.g., the present stage) and first connecting pads respectively from the two directly adjacent pixel driving circuits and in the same stage (e.g., the present stage).

FIG. 5D is a diagram illustrating the structure of a second conductive layer and a second semiconductor layer of two adjacent pixel driving circuits in an array substrate depicted in FIG. 3A. Referring to FIG. 3A, FIG. 3E, FIG. 3F, FIG. 4B, FIG. 5C, and FIG. 5D, the first portion P1 is a portion of the first branch GL_N_B1 that crosses over active layers respectively of second transistors respectively from two directly adjacent pixel driving circuits and in a same stage (e.g., the present stage). In some embodiments, the first portion P1 has a first average width w1 along a direction perpendicular to an extension direction of the first branch GL_N_B1; the second portion P2 has a second average width w2 along the direction perpendicular to the extension direction of the first branch GL_N_B1; and the first average width w1 is greater than the second average width w2.

Referring to FIG. 2, FIG. 3A, FIG. 3M, and FIG. 4A to FIG. 4C, in some embodiments, the second signal line layer SD2 includes a plurality of voltage supply lines (e.g., the respective voltage supply line Vdd), a plurality of data lines (e.g., the respective data line DL), and an anode contact pad ACP. Various appropriate conductive materials and various appropriate fabricating methods may be used to make the second signal line layer SD2. For example, a conductive material may be deposited on the substrate by a plasma-enhanced chemical vapor deposition (PECVD) process and patterned. Examples of appropriate conductive materials for making the second signal line layer SD2 include, but are not limited to, aluminum, copper, molybdenum, chromium, aluminum copper alloy, copper molybdenum alloy, molybdenum aluminum alloy, aluminum chromium alloy, copper chromium alloy, molybdenum chromium alloy, copper molybdenum aluminum alloy, and the like. Optionally, the plurality of voltage supply lines (e.g., the respective voltage supply line Vdd), the plurality of data lines (e.g., the respective data line DL), and the anode contact pad ACP are in a same layer.

FIG. 4D is a cross-sectional view along a D-D′ line in FIG. 3A. Referring to FIG. 2. FIG. 3A, FIG. 3J, and FIG. 4D, in some embodiments, the relay electrode RE is connected to the second electrode D4 of the fourth transistor T4 and the second electrode Dr2 of the second reset transistor Tr2 through a third via v3 extending through the passivation layer PVX, the second inter-layer dielectric layer ILD2, the first inter-layer dielectric layer ILD1, the insulating layer IN, and the gate insulating layer GI. An anode contact pad ACP is connected to the relay electrode RE through a fourth via v4 extending through the first planarization layer PLN1. An anode is connected to the anode contact pad ACP through a via extending through the second planarization layer PLN2.

Referring to FIG. 2, FIG. 3A, FIG. 3J, and FIG. 4C, in some embodiments, the voltage connecting pad VCP is connected to the third transistor T3 (e.g., to the first electrode S3 of the third transistor T3) through a fifth via v5 extending through the passivation layer PVX, the second inter-layer dielectric layer ILD2, the first inter-layer dielectric layer ILD1, the insulating layer IN, and the gate insulating layer GI. The respective voltage supply line Vdd of the plurality of voltage supply lines is connected to the voltage connecting pad VCP through a sixth via v6 extending through the first planarization layer PLN1. The voltage connecting pad VCP is connected to the second capacitor electrode Ce2 of the storage capacitor Cst through a seventh via v7 extending through the passivation layer PVX, the second inter-layer dielectric layer ILD2, and the first inter-layer dielectric layer ILD1.

Referring to FIG. 2, FIG. 3A, FIG. 3C, and FIG. 3J, in some embodiments, the respective second reset signal line Vint2 of a plurality of second reset signal lines is connected to the second reset transistor Tr2 (e.g., to the first electrode Sr2 of the second reset transistor Tr2) through a via extending through the passivation layer PVX, the second inter-layer dielectric layer ILD2, the first inter-layer dielectric layer ILD1, the insulating layer IN, and the gate insulating layer GI.

Referring to FIG. 2, FIG. 3A, FIG. 3E, FIG. 3F, FIG. 3J, and FIG. 4B, in some embodiments, the second connecting pad cp2 connects the first electrode Sr1 of the first reset transistor Tr1 and a respective first reset signal line Vint1 of a plurality of first reset signal lines. The second connecting pad cp2 is connected to the respective first reset signal line Vint1 through an eighth via v8 extending through the passivation layer PVX, the second inter-layer dielectric layer ILD2, and the first inter-layer dielectric layer ILD1. The second connecting pad cp2 is connected to a first electrode Sr1 of the first reset transistor Tr1 through a ninth via v9 extending through the passivation layer PVX, and the second inter-layer dielectric layer ILD2. Further, the second connecting pad cp2 is connected to a first electrode Sr1′ of a first reset transistor in an adjacent pixel driving circuit through a tenth via v10 extending through the passivation layer PVX, and the second inter-layer dielectric layer ILD2.

Referring to FIG. 2, FIG. 3A, FIG. 3C, FIG. 3F, FIG. 3J, and FIG. 4B, in some embodiments, the first connecting pad cp1 connects the first electrode Sd of the driving transistor Td and the second electrode D2 of the second transistor T2. The first connecting pad cp1 is connected to the first electrode Sd of the driving transistor Td through an eleventh via v11 extending through the passivation layer PVX, the second inter-layer dielectric layer ILD2, the first inter-layer dielectric layer ILD1, the insulating layer IN, and the gate insulating layer GI. The first connecting pad cp1 is connected to the second electrode D2 of the second transistor T2 through a twelfth via v12 extending the passivation layer PVX and the second inter-layer dielectric layer ILD2.

Referring to FIG. 2, FIG. 3A, FIG. 3O, and FIG. 4A to FIG. 4D, in some embodiments, the array substrate further includes an anode layer AD.

Referring to FIG. 2, FIG. 3A, FIG. 3P, and FIG. 4A to FIG. 4D, in some embodiments, the array substrate further includes a pixel definition layer PDL. The pixel definition layer PDL defines subpixel apertures SA, through which light emitting layers are respectively connected to anodes in respective pixel driving circuits.

FIG. 5E is a diagram illustrating the structure of a first semiconductor material layer and a light shield layer of two adjacent pixel driving circuits in an array substrate depicted in FIG. 3A. Referring to FIG. 5E, in some embodiments, an orthographic projection of the light shield LS on a base substrate covers at least 50% (e.g., at least 55%, at least 60%, at least 65%, at least 70%, at least 75%, at least 80%, at least 85%, at least 90%, at least 95%, at least 98%, at least 99%, or 100%) of an orthographic projection of an active layer ACTd of the driving transistor Td on the base substrate. By having this unique structure of the light shield LS at least partially covering the driving transistor Td, hysteresis characteristics of the driving transistor Td can be further improved, increasing a recovery rate of pixel brightness.

FIG. 5F is a diagram illustrating the structure of a first conductive layer and a light shield layer of two adjacent pixel driving circuits in an array substrate depicted in FIG. 3A. Referring to FIG. 5F, in some embodiments, an orthographic projection of the light shield LS on a base substrate covers at least 50% (e.g., at least 55%, at least 60%, at least 65%, at least 70%, at least 75%, at least 80%, at least 85%, at least 90%, at least 95%, at least 98%, at least 99%, or 100%) of an orthographic projection of a first capacitor electrode Ce1 of the storage capacitor on the base substrate.

FIG. 5G is a diagram illustrating the structure of a second conductive layer and a light shield layer of two adjacent pixel driving circuits in an array substrate depicted in FIG. 3A. Referring to FIG. 5G, in some embodiments, an orthographic projection of the light shield LS on a base substrate covers at least 50% (e.g., at least 55%, at least 60%, at least 65%, at least 70%, at least 75%, at least 80%, at least 85%, at least 90%, at least 95%, at least 98%, at least 99%, or 100%) of an orthographic projection of a second capacitor electrode Ce2 of the storage capacitor on the base substrate.

FIG. 5H is a diagram illustrating the structure of a second semiconductor material layer and a second signal line layer of two adjacent pixel driving circuits in an array substrate depicted in FIG. 3A. Referring to FIG. 5H, in some embodiments, an orthographic projection of the respective voltage supply line Vdd on a base substrate covers at least 50% (e.g., at least 55%, at least 60%, at least 65%, at least 70%, at least 75%, at least 80%, at least 85%, at least 90%, at least 95%, at least 98%, at least 99%, or 100%) of an orthographic projection of the active layer ACT2 of the second transistor on the base substrate. By having this unique structure, light irradiation on the active layer ACT2 of the second transistor can be prevented. Referring to FIG. 5H, in some embodiments, an orthographic projection of the respective voltage supply line Vdd on a base substrate covers at least 50% (e.g., at least 55%, at least 60%, at least 65%, at least 70%, at least 75%, at least 80%, at least 85%, at least 90%, at least 95%, at least 98%, at least 99%, or 100%) of an orthographic projection of the active layer ACTr1 of the first reset transistor on the base substrate. By having this unique structure, light irradiation on the active layer ACTr1 of the first reset transistor can be prevented.

FIG. 5I is a diagram illustrating the structure of a first signal line layer and a second signal line layer of two adjacent pixel driving circuits in an array substrate depicted in FIG. 3A. Referring to FIG. 5I, in some embodiments, the orthographic projection of the respective voltage supply line Vdd on the base substrate covers at least 50% (e.g., at least 55%, at least 60%, at least 65%, at least 70%, at least 75%, at least 80%, at least 85%, at least 90%, at least 95%, at least 98%, at least 99%, or 100%) of an orthographic projection of the node connecting line Cln on the base substrate. In some embodiments, at least a portion of the respective voltage supply line Vdd and at least a portion of the node connecting line Cln have conforming contours. In regions where they have conforming contours, edges of the respective voltage supply line Vdd and the node connecting line Cln are spaced apart from each other by a distance less than 3 μm.

Referring to FIG. 5I, in some embodiments, a first respective voltage supply line and a second respective voltage supply line respectively connected to a first pixel driving circuit PDC1 and a second pixel driving circuit PDC2 are connected to each other, forming a unitary structure US. In one example, in the unitary structure US, a boundary between the first respective voltage supply line and the second respective voltage supply line may be a virtual line between active layers of the second transistors from the first pixel driving circuit PDC1 and the second pixel driving circuit PDC2, respectively. In another example, in the unitary structure US, the boundary between the first respective voltage supply line and the second respective voltage supply line may be defined by a mirror symmetry plane that defines a mirror symmetry between corresponding layers of the first pixel driving circuit and corresponding layers of the second pixel driving circuit directly adjacent to each other and in the present stage, the mirror symmetry plane being perpendicular to a main surface of the array substrate and substantially parallel to the data lines in FIG. 3A.

The first pixel driving circuit PDC1 and the second pixel driving circuit PDC2 are directly adjacent to each other and in a same stage (e.g., the present stage). In some embodiments, an orthographic projection of the unitary structure US on a base substrate covers at least 50% (e.g., at least 55%, at least 60%, at least 65%, at least 70%, at least 75%, at least 80%, at least 85%, at least 90%, at least 95%, at least 98%, at least 99%, or 100%) of an orthographic projection of active layers of second transistors respectively of the first pixel driving circuit PDC1 and the second pixel driving circuit PDC2 on the base substrate, covers at least 50% (e.g., at least 55%, at least 60%, at least 65%, at least 70%, at least 75%, at least 80%, at least 85%, at least 90%, at least 95%, at least 98%, at least 99%, or 100%) of an orthographic projection of active layers of first reset transistors respectively of the first pixel driving circuit PDC1 and the second pixel driving circuit PDC2 on the base substrate.

Referring to FIG. 5I, in some embodiments, the orthographic projection of the unitary structure US on a base substrate covers at least 50% (e.g., at least 55%, at least 60%, at least 65%, at least 70%, at least 75%, at least 80%, at least 85%, at least 90%, at least 95%, at least 98%, at least 99%, or 100%) of an orthographic projection of node connecting lines respectively of the first pixel driving circuit PDC1 and the second pixel driving circuit PDC2 on the base substrate.

Referring to FIG. 5H and FIG. 5I, in some embodiments, the first respective voltage supply line and the second respective voltage supply line are between a first respective data line and a second respective data line respectively connected to the first pixel driving circuit PDC1 and the second pixel driving circuit PDC2.

Referring to FIG. 3A, FIG. 3C. FIG. 3J, and FIG. 3M, the array substrate in some embodiments further includes a third connecting pad cp3. The third connecting pad cp3 is connected to the first electrode S1 of the first transistor T1 through a via extending through the passivation layer PVX, the second inter-layer dielectric layer ILD2, the first inter-layer dielectric layer ILD1, the insulating layer IN, and the gate insulating layer GI. The respective data line DL is connected to the third connecting pad cp3 through a via extending through the first planarization layer PLN1.

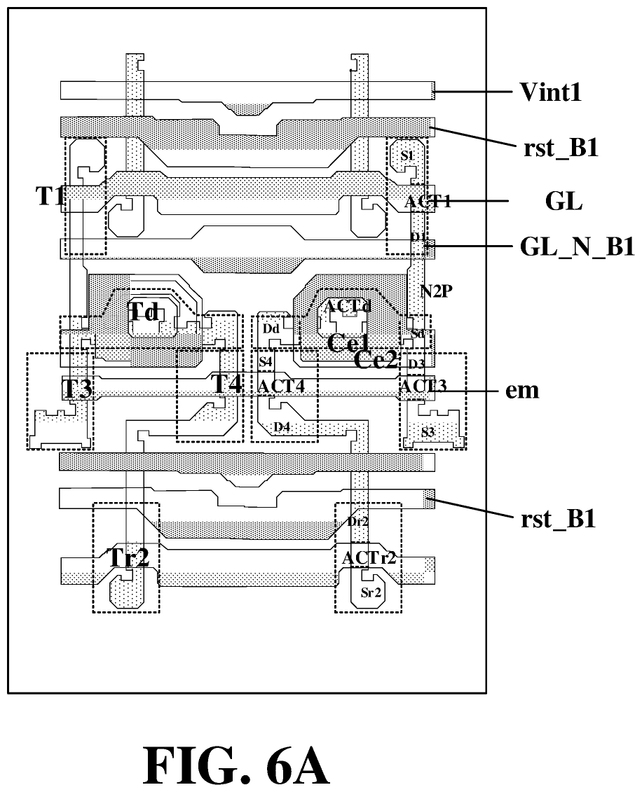

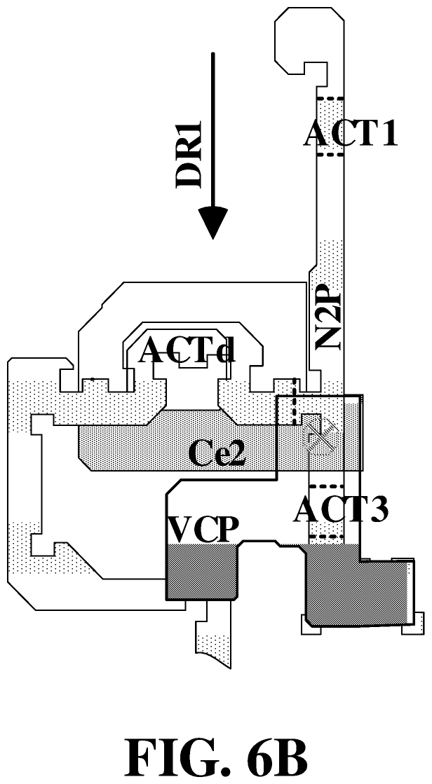

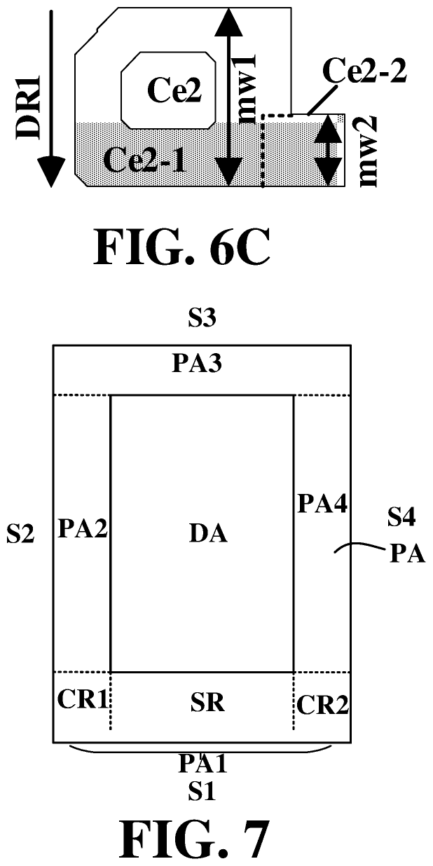

FIG. 6A is a diagram illustrating the structure of a first semiconductor material layer, a first conductive layer, and a second conductive layer of two adjacent pixel driving circuits in an array substrate depicted in FIG. 3A. Referring to FIG. 3A, FIG. 3C, FIG. 3E, and FIG. 6A, in some embodiments, an orthographic projection of a second node portion N2P on the base substrate is at least partially non-overlapping with an orthographic projection of the second capacitor electrode Ce2 on the base substrate. As used herein, the second node portion N2P is a portion of the first semiconductor material layer corresponding to the second node N2 depicted in FIG. 2. The second node portion N2P in some embodiments is a portion of the first semiconductor material layer in a region, boundary of the region is defined by the active layer ACTd of the driving transistor, the active layer ACT1 of the first transistor, and the active layer ACT3 of the third transistor. In some embodiments, the orthographic projection of a second node portion N2P on the base substrate is at least 30% (e.g., at least 40%, at least 50%, at least 60%, at least 70%, at least 80%, or at least 90%) non-overlapping with the orthographic projection of the second capacitor electrode Ce2 on the base substrate.

By reducing the overlapping between the second capacitor electrode Ce2 and the second node portion N2P, parasitic capacitance between the second capacitor electrode Ce2 and the second node portion N2P can be significantly reduced. The inventors of the present disclosure discover that the reduction in parasitic capacitance can significantly improve compensation capability of the driving transistor, enhancing display quality.

FIG. 6B is a zoom-in view of a region comprising a second node portion in an array substrate in some embodiments according to the present disclosure. FIG. 6C illustrates the structure of a second capacitor electrode in some embodiments according to the present disclosure. Referring to FIG. 6B and FIG. 6C, the second capacitor electrode Ce2 in some embodiments includes a first part Ce2-1 and a second part Ce2-2. Referring to FIG. 6A to FIG. 6C, an orthographic projection of the first part Ce2-1 on the base substrate is at least 90% (e.g., at least 91%, at least 92%, at least 93%, at least 94%, at least 95%, at least 96%, at least 97%, at least 98%, at least 99%, or 100%) non-overlapping with the orthographic projection of a second node portion N2P on the base substrate; and an orthographic projection of the second part Ce2-2 on the base substrate is partially overlapping with the orthographic projection of a second node portion N2P on the base substrate. Moreover, the orthographic projection of the second part Ce2-2 on the base substrate is at least 75% (e.g., at least 80%, at least 85%, at least 90%, at least 95%, at least 98%, at least 99%, or 100%) overlapping with an orthographic projection of the voltage connecting pad VCP on the base substrate. Accordingly, in some embodiments, the orthographic projection of the second capacitor electrode Ce2 on the base substrate is non-overlapping with an orthographic projection of a second node portion N2P on the base substrate, except for a part of the second capacitor electrode Ce2 (e.g., Ce2-2), the orthographic projection of which is at least 75% (e.g., at least 80%, at least 85%, at least 90%, at least 95%, at least 98%, at least 99%, or 100%) covered by the orthographic projection of the voltage connecting pad VCP on the base substrate.

Referring to FIG. 6C, a first maximum width mw1 of the first part Ce2-1 along a first direction DR1 is greater than (e.g., by at least 10%, by at least 20%, by at least 30%, by at least 40%, by at least 50%, by at least 60%, by at least 70%, by at least 80%, or by at least 90%) a second maximum width mw2 of the second part Ce2-2 along the first direction DR1. Optionally, the first direction DR1 is an extension direction of the second node portion N2P. Optionally, the first direction DR1 is a direction crossing over the respective first gate line GL, the respective light emitting control signal line em, and the respective second gate line (e.g., the first branch GL_N_B1).

FIG. 7 is a schematic diagram illustrating a display area and a peripheral area in an array substrate in some embodiments according to the present disclosure. Referring to FIG. 7, in some embodiments, the array substrate includes a display area DA and a peripheral area PA. In some embodiments, the peripheral area PA includes a first sub-area PA1 on a first side S1 of the display area DA, a second sub-area PA2 on a second side S2 of the display area DA, a third sub-area PA3 on a third side S3 of the display area DA, a fourth sub-area PA4 on a fourth side S4 of the display area DA. Optionally, the first side S1 and the third side S3 are opposite to each other. Optionally, the second side S2 and the fourth side S4 are opposite to each other. Optionally, the first sub-area PA1 is a sub-area where signal lines of the array substrate are connected to an integrated circuit.

As used herein, the term “display area” refers to an area of an array substrate where image is actually displayed. Optionally, the display area may include both a subpixel region and an inter-subpixel region. A subpixel region refers to a light emission region of a subpixel, such as a region corresponding to a pixel electrode in a liquid crystal display or a region corresponding to a light emissive layer in an organic light emitting diode display panel. An inter-subpixel region refers to a region between adjacent subpixel regions, such as a region corresponding to a black matrix in a liquid crystal display or a region corresponding a pixel definition layer in an organic light emitting diode display panel. Optionally, the inter-subpixel region is a region between adjacent subpixel regions in a same pixel. Optionally, the inter-subpixel region is a region between two adjacent subpixel regions from two adjacent pixels.

As used herein the term “peripheral area” refers to an area of an array substrate in a display panel where various circuits and wires are provided to transmit signals to the display substrate. To increase the transparency of a display apparatus having the array substrate, non-transparent or opaque components of the display apparatus (e.g., battery, printed circuit board, metal frame), can be disposed in the peripheral area rather than in the display areas.

In some embodiments, the first sub-area PA1 includes a side region SR and one or more corner regions (e.g., a first corner region CR1 and a second corner region CR2). The one or more corner regions are respectively at a corner of the display panel. The one or more corner regions respectively connect the side region SR to one or more adjacent sub-areas of the peripheral area PA. For example, the first corner region CR1 connects the side region SR to the second sub-area PA2, and the second corner region CR2 connects the side region SR to the fourth sub-area PA4.

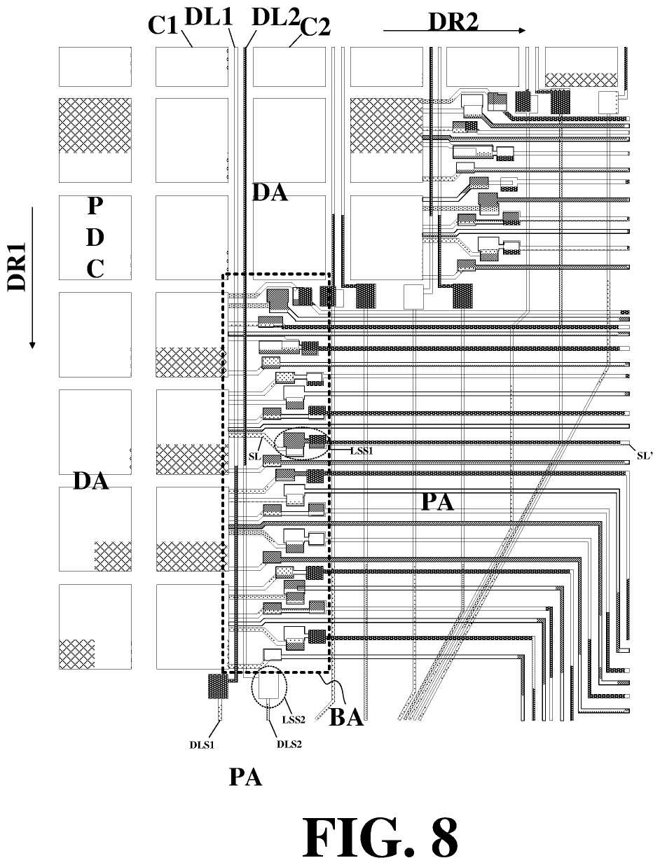

FIG. 8 illustrates the structure of a corner region in a first sub-area of an array substrate in some embodiments according to the present disclosure. Referring to FIG. 8, the plurality of data lines in some embodiments include a first adjacent data line DL1 and a second adjacent data line DL2, the first adjacent data line DL1 and the second adjacent data line DL2 extending along a first direction DR1. The first adjacent data line DL1 and the second adjacent data line DL2 extend from a display area DA into a boundary area BA, the boundary area BA being between the display area DA and the peripheral area PA (e.g., the second corner region CR2 as denoted in FIG. 7).

In some embodiments, the array substrate includes a plurality of columns of pixel driving circuits. The plurality of columns of pixel driving circuits includes a first column of pixel driving circuit C1 and a second column of pixel driving circuit C2. In the display area DA, the first adjacent data line DL1 and the second adjacent data line DL2 are in an inter-column region between the first column of pixel driving circuit C1 and the second column of pixel driving circuit C2. In the boundary area BA, the first adjacent data line DL1 and the second adjacent data line DL2 are between the first column of pixel driving circuit C1 and the peripheral area PA. The second column of pixel driving circuit C2 is absent in the boundary area BA. The first column of pixel driving circuit C1 is on a side of the first adjacent data line DL1 away from the second adjacent data line DL2 in the boundary area BA. Pixel driving circuits are absent in the boundary area BA. For example, pixel driving circuits are absent on a side of the second adjacent data line DL2 away from the first adjacent data line DL1 in the boundary area BA. In the boundary area BA, the first adjacent data line DL1 and the second adjacent data line DL2 are in a same layer.

In some embodiments, the array substrate includes a plurality of signal lines SL extending along a second direction DR2 from the boundary area BA into the peripheral area PA. The first adjacent data line DL1 and the second adjacent data line DL2 cross over the plurality of signal lines SL. The first adjacent data line DL1 and the second adjacent data line DL2 are in a same layer where they cross over a respective signal line of the plurality of signal lines SL. Examples of the plurality of signal lines SL include, inter alia, a respective first gate line GL, a respective light emitting control signal line em, a respective first reset signal line Vint1, a respective second reset signal line Vint2, a first branch rst_B1 of a respective reset control signal line, a second branch rst_B2 of the respective reset control signal line, a first branch GL_N_B1 of a respective second gate line, a second branch GL_N_B2 of the respective second gate line, a respective second reset signal line Vint2.

In some embodiments, the array substrate further includes a plurality of signal supply lines SL′ in the peripheral area PA respectively electrically connected to the plurality of signal lines SL in the boundary area BA. At least some of the plurality of signal supply lines SL′ in the peripheral area PA are in a layer different from corresponding signal lines in the boundary area BA. Optionally, the plurality of signal supply lines SL′ are alternately disposed in two different layers, e.g., alternately disposed in the first signal line layer SD1 and the second signal line layer SD2 as depicted in FIG. 4A.

In some embodiments, the array substrate further includes a plurality of first layer switching structure LSS1 in the boundary area BA. A respective first layer switching structure connects a pair of signal line and signal supply line in different layers. The respective first layer switching structure includes at least a portion extending through a via in at least one insulating layer, thereby connecting different conductive layers.

In some embodiments, the array substrate includes a column of layer switching structures in the boundary area BA. In the boundary area BA, the first adjacent data line DL1 and the second adjacent data line DL2 are between the first column of pixel driving circuit C1 and the column of layer switching structures. Optionally, the first column of pixel driving circuit C1 is present on a side of the first adjacent data line DL1 in the boundary area BA away from the second adjacent data line DL2. Optionally, the column of layer switching structures is present on side of the second adjacent data line DL2 away from the first adjacent data line DL1 in the boundary area BA.

In some embodiments, the array substrate further includes a first data signal supply line DLS1 and a second data signal supply line DLS2 in the peripheral area PA and outside the boundary area BA. The first data signal supply line DLS1 and the second data signal supply line DLS2 are respectively connected to the first adjacent data line DL1 and the second adjacent data line DL2 respectively through a plurality of second layer switching structures LSS2. A respective second layer switching structure connects a pair of data line and data signal supply line in different layers. The respective second layer switching structure includes at least a portion extending through a via in at least one insulating layer, thereby connecting different conductive layers.

The first data signal supply line DLS1 and the second data signal supply line DLS2 are in different layers. The first adjacent data line DL1 and the second adjacent data line DL2 are in a same layer that is different from those of the first data signal supply line DLS1 and the second data signal supply line DLS2. In one example, referring to FIG. 8 and FIG. 4A, the first adjacent data line DL1 and the second adjacent data line DL2 are in the second signal line layer SD2, the first data signal supply line DLS1 and the second data signal supply line DLS2 are in two different layers selected from the first conductive layer Gate1 and the second conductive layer Gate2.

In related array substrate, the adjacent data lines in the boundary area BA are typically disposed in two different layer, e.g., in the first conductive layer Gate1 and the second conductive layer Gate2, resulting in different impedance of the adjacent data lines in the boundary area BA. Because the adjacent data lines in the boundary area BA cross over a plurality of signal lines SL in the boundary area BA, parasitic capacitances between the adjacent data lines and the plurality of signal lines SL also differ from each other. The inventors of the present disclosure discover that, by having the adjacent data lines in the boundary area in a same layer, the difference in data loading in the adjacent data lines in the boundary area BA can be reduced or eliminated, improving display uniformity.

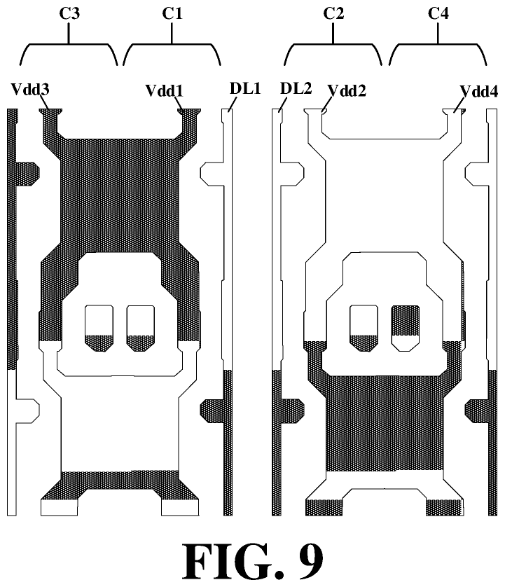

FIG. 9 illustrates the structure of a second signal line layer in a display area in an array substrate in some embodiments according to the present disclosure. Referring to FIG. 9, the first adjacent data line DL1 and the second adjacent data line DL2 are in a same inter-column region between a first column of pixel driving circuits C1 and a second column of pixel driving circuits C2. Moreover, the first adjacent data line DL1 and the second adjacent data line DL2 are between a first voltage supply line Vdd1 and a second voltage supply line Vdd2. The first adjacent data line DL1 and the second adjacent data line DL2 are configured to provide data signals to the first column of pixel driving circuits C1 and the second column of pixel driving circuits C2, respectively. The first voltage supply line Vdd1 and the second voltage supply line Vdd2 are configured to provide power supply voltages to the first column of pixel driving circuits C1 and the second column of pixel driving circuits C2, respectively.

In some embodiments, the array substrate includes a third column of pixel driving circuits C3, the first column of pixel driving circuits C1, the second column of pixel driving circuits C2, and a fourth column of pixel driving circuits C4, consecutively arranged side-by-side. The array substrate further includes a third voltage supply line Vdd3 and a fourth voltage supply line Vdd4. The third voltage supply line Vdd3 and the fourth voltage supply line Vdd4 are configured to provide power supply voltages to the third column of pixel driving circuits C3 and the fourth column of pixel driving circuits C4, respectively. The third voltage supply line Vdd3 and the first voltage supply line Vdd1 are connected to each other. The fourth voltage supply line Vdd4 and the second voltage supply line Vdd2 are connected to each other.

In another aspect, the present invention provides a display apparatus, including the array substrate described herein or fabricated by a method described herein, and one or more integrated circuits connected to the array substrate. Examples of appropriate display apparatuses include, but are not limited to, an electronic paper, a mobile phone, a tablet computer, a television, a monitor, a notebook computer, a digital album, a GPS, etc. Optionally, the display apparatus is an organic light emitting diode display apparatus. Optionally, the display apparatus is a mini light emitting diode display apparatus. Optionally, the display apparatus is a micro light emitting diode display apparatus. Optionally, the display apparatus is a quantum dots light emitting diode display apparatus.

The foregoing description of the embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to exemplary embodiments of the invention does not imply a limitation on the invention, and no such limitation is to be inferred. The invention is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

1. An array substrate, comprising a first adjacent data line and a second adjacent data line extending along a first direction;
wherein the first adjacent data line and the second adjacent data line extend from a same inter-column region between a first column of pixel driving circuit and a second column of pixel driving circuit in a display area into a boundary area between the first column of pixel driving circuit and a peripheral area;
wherein, in the boundary area, the first adjacent data line and the second adjacent data line are in a same layer.

2. The array substrate of claim 1, wherein the first column of pixel driving circuit is on a side of the first adjacent data line away from the second adjacent data line in the boundary area; and
the second column of pixel driving circuit is absent on a side of the second adjacent data line away from the first adjacent data line in the boundary area.

3. The array substrate of claim 1, further comprising a plurality of signal lines extending along a second direction from the boundary area into the peripheral area;
wherein the first adjacent data line and the second adjacent data line are in a same layer where they cross over the plurality of signal lines.

4. The array substrate of claim 3, further comprising:
a plurality of first layer switching structure in the boundary area; and
a plurality of signal supply lines in the peripheral area respectively electrically connected to the plurality of signal lines in the boundary area;
wherein a respective first layer switching structure connects a pair of signal line and signal supply line in different layers.

5. The array substrate of claim 1, further comprising a column of layer switching structures in the boundary area;
wherein, in the boundary area, the first adjacent data line and the second adjacent data line are between the first column of pixel driving circuit and the column of layer switching structures.

6. The array substrate of claim 1, further comprising a first data signal supply line and a second data signal supply line outside the boundary area and in the peripheral area;
wherein the first data signal supply line and the second data signal supply line are respectively connected to the first adjacent data line and the second adjacent data line respectively through a plurality of second layer switching structures; and
the first data signal supply line and the second data signal supply line are in different layers from each other, and are in layers different from the first adjacent data line and the second adjacent data line.

7. The array substrate of claim 1, wherein the first adjacent data line and the second adjacent data line are between a first voltage supply line and a second voltage supply line;
the first adjacent data line and the second adjacent data line are configured to provide data signals to the first column of pixel driving circuits and the second column of pixel driving circuits, respectively; and
the first voltage supply line and the second voltage supply line are configured to provide power supply voltages to the first column of pixel driving circuits and the second column of pixel driving circuits, respectively.

8. The array substrate of claim 1, wherein a respective pixel driving circuit comprises:
a second capacitor electrode connected to a respective voltage supply line; and
a first semiconductor material layer comprising a second node portion, a boundary of which being defined by an active layer of a driving transistor, an active layer of a first transistor, and an active layer of a third transistor;
wherein an orthographic projection of the second node portion on a base substrate is at least partially non-overlapping with an orthographic projection of the second capacitor electrode on the base substrate.

9. The array substrate of claim 8, wherein the orthographic projection of the second node portion on the base substrate is at least 50% non-overlapping with an orthographic projection of the second capacitor electrode on the base substrate.

10. The array substrate of claim 8, wherein the second capacitor electrode comprises a first part and a second part;
an orthographic projection of the first part on the base substrate is at least 90% non-overlapping with the orthographic projection of the second node portion on the base substrate; and
an orthographic projection of the second part on the base substrate is at least partially overlapping with the orthographic projection of the second node portion on the base substrate.

11. The array substrate of claim 10, wherein the respective pixel driving circuit further comprises a voltage connecting pad connected to a first electrode of the third transistor, a respective voltage supply line, and the second capacitor electrode.

12. The array substrate of claim 11, wherein the orthographic projection of the second part on the base substrate is at least 75% overlapping with an orthographic projection of the voltage connecting pad on the base substrate; and
the orthographic projection of the first part on the base substrate is non-overlapping with the orthographic projection of the voltage connecting pad on the base substrate.

13. The array substrate of claim 10, wherein the second node portion extends along a first direction crossing over a respective gate line; and
a first maximum width of the first part along the first direction is greater than a second maximum width of the second part along the first direction by at least 30%.

14. The array substrate of claim 1, comprising a first semiconductor material layer and a second semiconductor material layer;
wherein the second semiconductor material layer comprise at least an active layer of a second transistor and at least an active layer of a first reset transistor;
the first semiconductor material layer comprise at least an active layer of a driving transistor comprising a first semiconductor material; and
active layers of the second transistor and the first reset transistor comprise a second semiconductor material different from the first semiconductor material.

15. The array substrate of claim 14, wherein an orthographic projection of a respective voltage supply line on a base substrate covers at least 50% of an orthographic projection of the active layer of the second transistor on the base substrate, covers at least 50% of an orthographic projection of the active layer of the first reset transistor on the base substrate.

16. The array substrate of claim 1, further comprising a respective second gate line connected to a gate electrode of a second transistor;
the respective second gate line comprises a first branch in a second conductive layer and a second branch in a third conductive layer; and
an orthographic projection of the first branch on a base substrate at least partially overlaps with an orthographic projection of the second branch on the base substrate.

17. The array substrate of claim 1, further comprising a respective reset control signal line connected to a gate electrode of a first reset transistor;
the respective reset control signal line comprises a first branch in a second conductive layer and a second branch in a third conductive layer; and
an orthographic projection of the first branch on a base substrate at least partially overlaps with an orthographic projection of the second branch on the base substrate.

18. The array substrate of claim 1, wherein a respective pixel driving circuit comprises a node connecting line, a second transistor, a first reset transistor, and a storage capacitor;
wherein the node connecting line connects a first electrode of the second transistor and a second electrode of the first reset transistor to a first capacitor electrode of the storage capacitor; and
an orthographic projection of a respective voltage supply line on a base substrate covers at least 50% of an orthographic projection of the node connecting line on the base substrate.

19. The array substrate of claim 18, wherein at least a portion of the respective voltage supply line and at least a portion of the node connecting line have conforming contours.

20. A display apparatus, comprising the array substrate of claim 1, and an integrated circuit connected to the array substrate.
